(19) United States
(12) Patent Application Publication
(10) Pub. No.: US 2026/0276750 A1
(43) Pub. Date: Sep. 17, 2026

(54) MAGNETIC SENSOR

(71) Applicant: TDK Corporation, Tokyo (JP)

(72) Inventor: Norikazu OTA, Tokyo (JP)

(73) Assignee: TDK Corporation, Tokyo (JP)

(21) Appl. No.: 19/560,240

(22) Filed: Mar. 9, 2026

(30) Foreign Application Priority Data
Mar. 11, 2025 (JP) 2025-038246
Jan. 28, 2026 (JP) 2026-011817

(51) Int. Cl. G01R 33/09; G01R 33/00

(52) U.S. Cl. CPC G01R 33/093; G01R 33/098; G01R 33/0094

(57) ABSTRACT

A magnetic sensor includes a first magnetoresistive (MR) element, a second MR element, and a third MR element. The magnetization of a magnetization pinned layer of each of the first, second, and third MR elements includes a component in a first direction. The second MR element is arranged at a first interval from the first MR element in the first direction. The third MR element is arranged at a second interval from the first MR element in a second direction. The first interval is at least 0.5 times D and at most 3 times D, where D is the maximum dimension of at least one of the first, the second, and the third MR elements.

### CROSS-REFERENCE TO RELATED APPLICATIONS

This application claims the benefit of Japanese Priority Patent Application No. 2025-038246 filed on Mar. 11, 2025, and Japanese Priority Patent Application No. 2026-011817 filed on Jan. 28, 2026, the entire contents of each of which are incorporated herein by reference.

### BACKGROUND

The disclosure relates to a magnetic sensor including a magnetoresistive element including a free layer configured to have a magnetic vortex structure.

Magnetic sensors using magnetoresistive elements have been used for various applications in recent years. A magnetoresistive element includes a magnetization pinned layer in which a direction of magnetization is fixed, a free layer in which a direction of magnetization can be changed in accordance with a direction of an applied magnetic field, and an intermediate layer arranged between the magnetization pinned layer and the free layer.

For example, WO 2020/250489 discloses a magnetic field strength sensor using a magnetoresistive element including a free layer having a magnetic vortex structure.

M. Natali, A. Popa, U. Ebels, Y. Chen, S. Li, and M. E. Welland, “Correlated vortex chiralities in interacting permalloy dot patterns,” Journal of Applied Physics, Vol. 96, No. 8, pp. 4334-4341 (2004) discloses formation and disappearance of magnetic vortices due to magnetostatic interactions in two polycrystalline permalloy dot patterns having a magnetic vortex structure.

It is desirable for a magnetic sensor to have an appropriate sensitivity to changes in the magnetic field.

### SUMMARY

A magnetic sensor according to a first aspect of the disclosure includes a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The plurality of magnetoresistive elements include a first element, a second element, and a third element. Magnetization of the magnetization pinned layer of each of the first element, the second element, and the third element includes a component in a first direction. The second element is arranged at a first interval from the first element in the first direction. The third element is arranged at a second interval from the first element in a second direction different from the first direction. Each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape. The first interval is at least 0.5 times D and at most 3 times D, where D is the maximum dimension of at least one of the first element, the second element, and the third element.

A magnetic sensor according to a second aspect of the disclosure includes a first magnetoresistive element, and a second magnetoresistive element arranged at a first interval from the first magnetoresistive element in a first direction. Each of the first magnetoresistive element and the second magnetoresistive element includes a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The magnetization of the magnetization pinned layer includes a component in the first direction. Each of the first magnetoresistive element and the second magnetoresistive element has a planar shape in a plan view from a stacking direction of the magnetization pinned layer, the intermediate layer, and the free layer, the planar shape having a maximum dimension being a greatest distance between any two points on an outer edge of the planar shape. The first interval is at least 0.5 times D and at most 3 times D, where D is the maximum dimension of at least one of the first magnetoresistive element and the second magnetoresistive element.

A magnetic sensor according to a third aspect of the disclosure includes a substrate including a first inclined surface and a second inclined surface each extending in a first direction and facing in different directions, and a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The plurality of magnetoresistive elements include a first element arranged on the first inclined surface, a second element arranged on the first inclined surface and spaced from the first element in the first direction, a third element arranged on the second inclined surface and spaced from the first element in a second direction different from the first direction. The magnetization pinned layer, the intermediate layer, and the free layer of each of the first element and the second element are stacked in a direction intersecting with the first inclined surface. The magnetization pinned layer, the intermediate layer, and the free layer of the third element are stacked in a direction intersecting with the second inclined surface. Each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape. An interval between the first element and the third element in a third direction is at least 0.5 times D and at most 3 times D, where D is the maximum dimension of at least one of the first element, the second element, and the third element. The third direction is orthogonal to the first direction, intersects with the second direction at an angle other than 90 degrees, and is parallel to the first inclined surface.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a perspective view showing an example of a part of a magnetic sensor according to a first example embodiment of the disclosure.

FIG. 2 is a plan view showing a part of the magnetic sensor shown in FIG. 1.

FIG. 3 is a sectional view showing a part of the magnetic sensor 1 shown in FIG. 1.

FIG. 4 is a plan view showing another example of a part of the magnetic sensor according to the first example embodiment of the disclosure.

FIG. 5 is a perspective view showing the magnetoresistive element in the first example embodiment of the disclosure.

FIG. 6 is a characteristic chart schematically showing a relationship between magnetic flux density and a resistance value of the magnetoresistive element in the first example embodiment of the disclosure.

FIG. 7A is an explanatory diagram schematically illustrating a relationship between the magnitude of the magnetic flux density and a magnetic vortex structure in the first example embodiment of the disclosure.

FIG. 7B is an explanatory diagram schematically showing a relationship between the magnitude of the magnetic flux density and the magnetic vortex structure in the first example embodiment of the disclosure.

FIG. 7C is an explanatory diagram schematically showing a relationship between the magnitude of the magnetic flux density and the magnetic vortex structure in the first example embodiment of the disclosure.

FIG. 7D is an explanatory diagram schematically illustrating a relationship between the magnitude of the magnetic flux density and a magnetic vortex structure in the first example embodiment of the disclosure.

FIG. 7E is an explanatory diagram schematically showing a relationship between the magnitude of the magnetic flux density and the magnetic vortex structure in the first example embodiment of the disclosure.

FIG. 8 is a characteristic chart showing a relationship between the magnitude of a magnetic field and the magnitude of magnetization of an entire free layer in the first example embodiment of the disclosure.

FIG. 9A is a characteristic chart showing a first characteristic of sensitivity in the first example embodiment of the disclosure.

FIG. 9B is a characteristic chart showing a second characteristic of the sensitivity in the first example embodiment of the disclosure.

FIG. 10A is a characteristic chart showing a third characteristic of the sensitivity in the first example embodiment of the disclosure.

FIG. 10B is a characteristic chart showing a fourth characteristic of the sensitivity in the first example embodiment of the disclosure.

FIG. 11 is a schematic diagram showing four magnetoresistive elements in the first example embodiment of the disclosure.

FIG. 12 is a characteristic chart showing a relationship between an element interval of the four magnetoresistive elements and an occupied area of the magnetic sensor in the first example embodiment of the disclosure.

FIG. 13 is a characteristic chart showing a relationship between the element interval of the four magnetoresistive elements and noise in the first example embodiment of the disclosure.

FIG. 14 is a perspective view showing a part of the magnetic sensor according to a second example embodiment of the disclosure.

FIG. 15 is a plan view showing a part of the magnetic sensor shown in FIG. 14.

FIG. 16 is a sectional view showing a part of the magnetic sensor shown in FIG. 14.

FIG. 17 is a perspective view showing a part of a magnetic sensor according to a third example embodiment of the disclosure.

FIG. 18 is a plan view of a part of the magnetic sensor shown in FIG. 17.

FIG. 19 is a sectional view of the magnetic sensor shown in FIG. 17.

FIG. 20 is a circuit diagram showing a circuit configuration of a magnetic sensor device according to a fourth example embodiment of the disclosure.

FIG. 21 is a characteristic chart schematically showing a differential output according to the fourth example embodiment of the disclosure.

FIG. 22 is a schematic diagram showing a magnetic sensor device according to a fifth example embodiment of the disclosure.

FIG. 23A is a perspective view showing an imaging device according to a sixth example embodiment of the disclosure.

FIG. 23B is a perspective view showing an imaging device according to a seventh example embodiment of the disclosure.

### DETAILED DESCRIPTION

Recently, a magnetic sensor capable of detecting a weak magnetic field of a detection target with high accuracy has been required. Hereinafter, the magnetic field of the detection target is also referred to as a target magnetic field.

An object of the disclosure is to provide a magnetic sensor capable of detecting a change in a magnetic field with appropriate sensitivity.

In the following, some example embodiments and modification examples of the disclosure will be described in detail with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. The description is given in the following order.

### First Example Embodiment

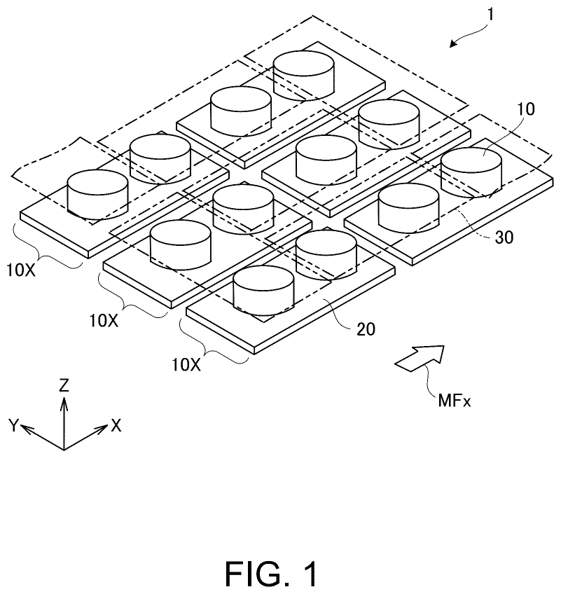

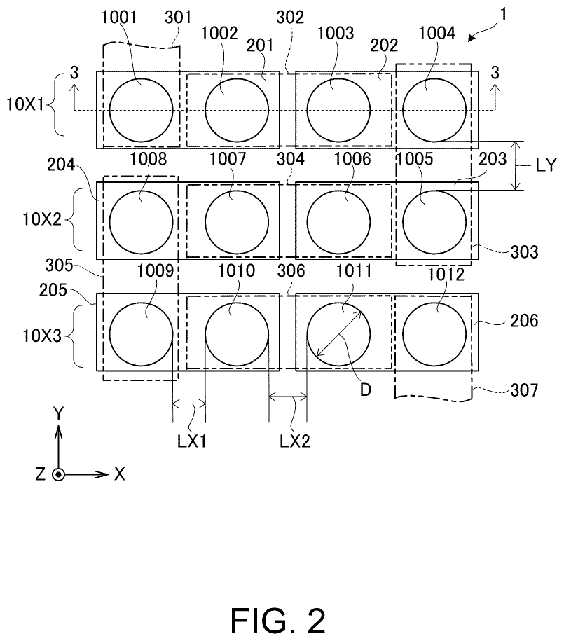

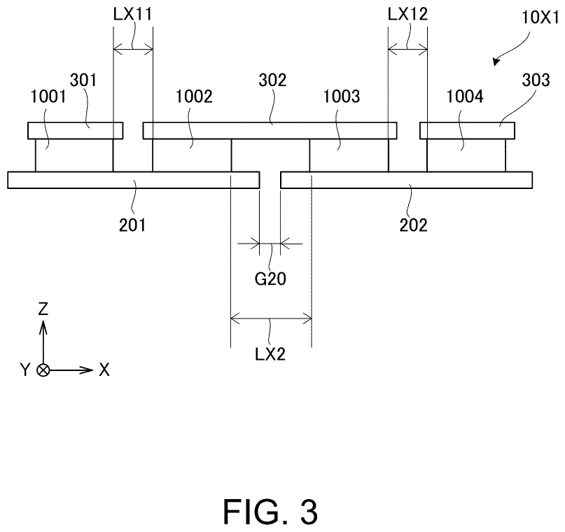

First, with reference to FIG. 1, FIG. 2, and FIG. 3, a schematic configuration of a magnetic sensor according to a first example embodiment of the disclosure is described. The magnetic sensor 1 corresponds to a specific example of the magnetic sensor according to one aspect of the disclosure. FIG. 1 is a perspective view showing a part of the magnetic sensor 1. FIG. 2 is a plan view showing a part of the magnetic sensor 1. FIG. 3 is a sectional view showing a part of the magnetic sensor 1. Note that FIG. 3 illustrates a cross section taken along line 3-3 illustrated in FIG. 2.

The magnetic sensor 1 detects a magnetic field component MFx parallel to the X-axis direction in a magnetic field applied to the magnetic sensor 1, and generates a detection signal corresponding to the strength of the magnetic field component MFx parallel to the X-axis direction. As shown in FIG. 1, the magnetic sensor 1 includes a plurality of magnetoresistive elements 10, a plurality of lower electrodes 20, and a plurality of upper electrodes 30. In the following description, the magnetoresistive elements will be referred to as MR elements. The lower electrode is also referred to as a lower lead. The upper electrode is also referred to as an upper lead. In FIGS. 1 to 3, the plurality of upper electrodes 30 are illustrated by two dot chain lines for convenience.

Here, an X direction, a Y direction, and a Z direction will be defined as shown in FIGS. 1 to 3. The X, Y, and Z directions are orthogonal to each other. The opposite directions to the X, Y, and Z directions are defined as −X, −Y, and −Z directions, respectively. For convenience of description, the X, Y, and Z directions are also referred to as a +X, +Y, and +Z directions, respectively. In FIGS. 2 and 3, the +Z direction is illustrated by a symbol indicating a direction perpendicular to the plane of the drawing. The symbol with solid circle indicates the direction from the back of the plane of the drawing to the front.

Hereinafter, an axis parallel to the +X direction or the −X direction is referred to as an X axis. A direction parallel to the +X direction or the −X direction is referred to as an X-axis direction. An axis parallel to the +Y direction or the −Y direction is referred to as a Y axis. A direction parallel to the +Y direction or the −Y direction is referred to as a Y-axis direction. An axis parallel to the +Z direction or the −Z direction is referred to as a Z axis. A direction parallel to the +Z direction or the −Z direction is referred to as a Z-axis direction. A plane perpendicular to the Z axis is referred to as an XY plane. The XY plane is also a plane parallel to both the X-axis direction and the Y-axis direction.

The term “above” refers to positions located forward of a reference position in the Z direction, and “below” refers to positions located on a side of the reference position opposite from “above”. For each component of the magnetic sensor 1, the term “top surface” refers to a surface of the component located at the end thereof in the Z direction, and the term “bottom surface” refers to a surface of the component located at the end thereof in the −Z direction. For each component of the magnetic sensor 1, the shape in a plan view from the +Z direction is referred to as a “planar shape”.

The plurality of MR elements 10 are spaced apart from each other along the XY plane. In the example shown in FIG. 1, four MR elements 10 are arranged at intervals along the X-axis direction, and three MR elements 10 are arranged at intervals along the Y-axis direction. Here, a group of the plurality of MR elements 10 arranged along the X-axis direction is referred to as an element group 10X. In the example shown in FIG. 1, three element groups 10X are arranged at intervals along the Y-axis direction.

In FIGS. 2 and 3, twelve MR elements 10 are denoted by reference numerals 1001, 1002, 1003, 1004, 1005, 1006, 1007, 1008, 1009, 1010, 1011, and 1012, respectively, to distinguish the twelve MR elements 10. In order to distinguish the three element groups 10X, the three element groups 10X are denoted by reference numerals 10X1, 10X2, and 10X3, respectively. The element group 10X1 is located at an end in the Y direction. The element group 10X3 is located at the end in the −Y direction. The element group 10X2 is located between the element group 10X1 and the element group 10X2.

The element group 10X1 includes four MR elements 1001 to 1004 arranged in this order along the X direction. The element group 10X2 includes four MR elements 1005 to 1008 arranged in this order along the −X direction. The element group 10X3 includes four MR elements 1009 to 1012 arranged in this order along the X direction.

Note that the number of the element groups 10X and the number of the MR elements 10 included in each element group 10X are not limited to the example shown in FIGS. 1 to 3, and may be 11 or less or 13 or more.

The arrangement of the MR elements 10 is not limited to the example shown in FIGS. 1 to 3. The MR elements 10 may be shifted in the X-axis direction or the Y-axis direction in unit of the MR element, or may be shifted in the X-axis direction or the Y-axis direction in unit of the element group 10X.

The plurality of MR elements 10 are connected in series to each other by the plurality of lower electrodes 20 and the plurality of upper electrodes 30. The plurality of lower electrodes 20 are arranged under the plurality of MR elements 10. The plurality of upper electrodes 30 are arranged over the plurality of MR elements 10. The plurality of lower electrodes 20 and the plurality of upper electrodes 30 are arranged to face each other in the Z-axis direction with the plurality of MR elements 10 interposed therebetween. In the example shown in FIGS. 1 to 3, the plurality of MR elements 10, the plurality of lower electrodes 20, and the plurality of upper electrodes 30 are connected so as to form a meander shape as a whole in plan view from the Z direction.

In FIG. 2, in order to distinguish the six lower electrodes 20, reference numerals 201, 202, 203, 204, 205, and 206 are given to the six lower electrodes 20, respectively. In FIG. 2, in order to distinguish the seven upper electrodes 30, reference numerals 301, 302, 303, 304, 305, 306, and 307 are given to the seven upper electrodes 30, respectively.

In the element group 10X1, the MR elements 1001 and 1002 are arranged on the lower electrode 201 and are electrically connected to each other by the lower electrode 201. The MR elements 1003 and 1004 are arranged on the lower electrode 202 and are electrically connected to each other by the lower electrode 202. The MR elements 1002 and 1003 are arranged under the upper electrode 302 and are electrically connected to each other by the upper electrode 302.

The upper electrode 301 is arranged on the MR element 1001 and electrically connected to the MR element 1001. The upper electrode 303 is arranged on the MR element 1004 and electrically connected to the MR element 1004. For example, detection current flowed into the upper electrode 301 passes through the MR element 1001, the lower electrode 201, the MR element 1002, the upper electrode 302, the MR element 1003, the lower electrode 202, and the MR element 1004 in this order and reaches the upper electrode 303.

The element group 10X2 has the same configuration as the element group 10X1. Specifically, the MR elements 1005 and 1006 are electrically connected to each other by the lower electrode 203. The MR elements 1006 and 1007 are electrically connected to each other by the upper electrode 304. The MR elements 1007 and 1008 are electrically connected to each other by the lower electrode 204. The upper electrode 303 is arranged on the MR element 1005 and electrically connects the MR element 1004 and 1005. The upper electrode 305 is arranged on the MR element 1008 and is electrically connected to the MR element 1008.

The element group 10X3 has the same configuration as the element group 10X1. Specifically, the MR elements 1009 and 1010 are electrically connected by the lower electrode 205. The MR elements 1010 and 1011 are electrically connected by the upper electrode 306. The MR elements 1011 and 1012 are electrically connected by the lower electrode 206. The upper electrode 305 is arranged on the MR element 1009 and electrically connects the MR element 1008 and 1009. The upper electrode 307 is arranged on the MR element 1012 and is electrically connected to the MR element 1012.

The plurality of MR elements 1001 to 1012 may be connected in series by the plurality of lower electrodes 201 to 206 and the plurality of upper electrodes 301 to 307. Therefore, in the magnetic sensor 1, for example, detection current flowing into the upper electrode 301 passes through each of the plurality of MR elements 1001 to 1012. Note that, in the example shown in FIGS. 1 to 3, the plurality of MR elements 10 are connected in series. However, at least some of the plurality of MR elements 10 may be connected in parallel. Alternatively, a plurality of sets each including a plurality of MR elements 10 connected in parallel may be connected in series, or a plurality of sets each including a plurality of MR elements 10 connected in series may be connected in parallel.

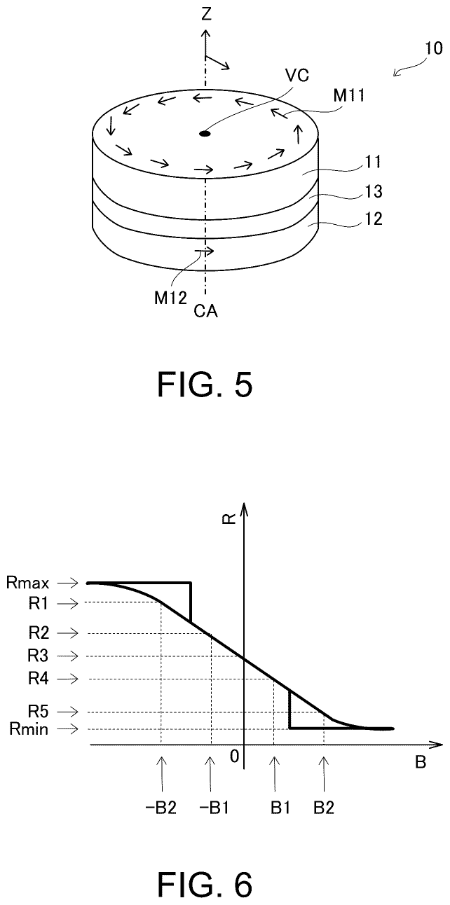

Now, a configuration of MR element 10 will be described with reference to FIG. 5. FIG. 5 is a perspective view showing the MR element 10. The MR element 10 has a stacked structure in which layers are stacked along the central axis CA. In the following description, the stacking direction of the MR element 10 is assumed to be the Z-axis direction. In this case, the central axis CA is parallel or substantially parallel to the Z-axis direction. With respect to the MR element 10, a direction orthogonal to the Z-axis direction is defined as an r direction. The r direction represents an in-plane direction orthogonal to the Z-axis direction, and does not represent a specific fixed direction.

The MR element 10 is, for example, a spin-valve MR element having a stacked structure in which a free layer 11, an intermediate layer 13, and a magnetization pinned layer 12 are stacked in order along the Z-axis direction. In the example shown in FIG. 5, the free layer 11, the intermediate layer 13, and the magnetization pinned layer 12 are stacked in this order in the −Z direction, but the free layer 11, the intermediate layer 13, and the magnetization pinned layer 12 may be stacked in this order in the +Z direction.

The spin-valve MR element is a giant magnetoresistive element (hereinafter, referred to as a GMR element), or a tunnel magnetoresistive element (hereinafter, referred to as a TMR element). Hereinafter, the giant magnetoresistive element is referred to as a GMR element, and the tunnel magnetoresistive element is referred to as a TMR element.

When the MR element 10 is a GMR element, the intermediate layer 13 is a nonmagnetic conductive layer made of a platinum group element such as ruthenium (Ru) or gold (Au), or a nonmagnetic metal such as copper (Cu). When the MR element 10 is a TMR element, the intermediate layer 13 is a nonmagnetic tunnel barrier layer made of a metal oxide such as magnesium oxide (MgO). When the intermediate layer 13 is a tunnel barrier layer, the intermediate layer 13 has a thickness thin enough to allow a tunnel current based on quantum mechanics to pass therethrough.

A direction or strength of magnetization of the free layer 11 varies according to an external magnetic field. The free layer 11 is configured to have a so-called spin vortex structure. In the example embodiment, the material and structure of the free layer 11 are selected so as to develop a magnetic vortex along the XY plane orthogonal to the Z-axis direction. The free layer 11 includes a magnetic vortex structure M11 that swirls around a vortex core VC along the XY plane. The free layer 11 is a soft ferromagnetic layer and is made of, for example, CoFe, NiFe, CoFeB, or the like.

The magnetization pinned layer 12 is, for example, a hard ferromagnetic layer whose magnetization includes a component in the X-axis direction, and is made of CoFe, NiFe, CoFeB, or the like. In the example shown in FIG. 5, the magnetization of the magnetization pinned layer 12 includes a component in the +X direction. Note that, as long as the magnetization of the magnetization pinned layer 12 includes a component in a specific direction as a main component, the magnetization of the magnetization pinned layer 12 may include a component in a direction other than the specific direction. Hereinafter, the direction of the main component of the magnetization of the magnetization pinned layer 12 will be described as a direction M12 of the magnetization of the magnetization pinned layer 12.

The direction M12 of the magnetization of the magnetization pinned layer 12 is fixed in the specific direction. The expression “the direction of magnetization is fixed” may mean that the direction of magnetization does not vary by action of the magnetic field at least in a strength range of the magnetic field to be detected by the MR element 10. The direction M12 of the magnetization of the magnetization pinned layer 12 is also referred to as a sensitive axis direction of the MR element 10. When the direction M12 of the magnetization of the magnetization pinned layer 12 is the +X direction or the −X direction, the sensitive axis direction is the X-axis direction.

In the example embodiment, the MR element 10 is a current-perpendicular-to-plane (CPP) type MR element in which the detection current for signal detection is caused to flow in a direction (in the Z-axis direction) substantially perpendicular to the respective surfaces of the free layer 11, the intermediate layer 13, and the magnetization pinned layer 12. When the detection current flows in the Z-axis direction through the MR element 10 to which an external magnetic field is applied, the resistance value of the MR element 10 varies according to the external magnetic field.

The planar shape of the MR element 10 may be an isotropic shape or an anisotropic shape. The “isotropic shape” is a concept including, for example, a “regular polygon” such as a regular hexagon or a regular octagon in addition to a circle. Note that the circular shape, which is an example of the “isotropic shape”, is not limited to a perfect circle, which is a geometrically accurate circle, and may be a circle that conceptually allows an error such as a manufacturing error and a measurement error. For example, a slight cutout, recess, protrusion, or the like may be included in a part of the circumference. The circular shape, which is an example of the “isotropic shape”, may be slightly flattened. For example, the ratio of the minimum diameter to the maximum diameter may be 0.9 or more and 1.0 or less.

The regular polygon, which is another example of the “isotropic shape”, is not limited to a geometrically accurate regular polygon, and may be a regular polygon of a concept that allows an error such as a manufacturing error or a measurement error. For example, a slight cutout, recess, protrusion, or the like may be included in a part of the outer edge. The lengths of the sides constituting the regular polygon may be different from each other by about 10% or less.

The “anisotropic shape” may be an elliptical shape, a shape in which a recess, a flat portion, a protrusion, or the like is provided in a part of an ellipse, a rectangular shape, or a D shape, as long as the magnetic vortex structure is developed in the free layer 11.

The planar shape of the magnetization pinned layer 12 may be the same or substantially the same as the planar shape of the free layer 11. The planar shape of at least a part of the magnetization pinned layer 12 may be larger than the planar shape of the free layer 11.

In the example shown in FIG. 5, the planar shape of the MR element 10 is circular, and the MR element 10 has a substantially cylindrical external appearance. However, the MR element 10 may have an appearance of a substantially truncated cone shape, or may have an appearance of a three dimensional shape corresponding to the planar shape of the MR element 10.

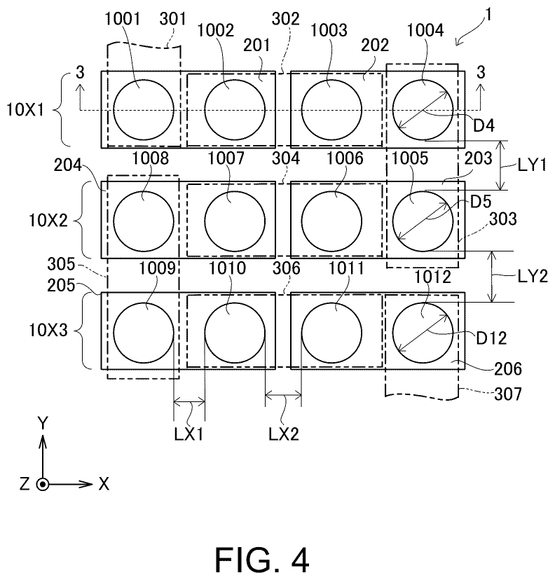

The MR element 10 has the maximum dimension at which a distance between two points on the outer edge of the planar shape in the plan view from the +Z direction is maximized. When the planar shape of the MR element 10 is circular, the maximum dimension represents the diameter of the circle. Hereinafter, the maximum dimension of the MR element 10 may be referred to as a dimension D or simply as D. FIG. 2 illustrates a case where the plurality of MR elements 10 (the MR elements 1001 to 1012) have the same dimension D. FIG. 4 is a plan view showing another example of a part of the magnetic sensor 1. FIG. 4 illustrates a case where the dimension D of one of two MR elements 10 arranged in the specific direction is different from the dimension D of the other of the two MR elements 10.

Next, features of the arrangement of the MR element 10 will be described with reference to FIGS. 1 to 3. Hereinafter, a direction of the sensitivity axis of the MR element 10 may be referred to as a first direction. The first direction is also the direction M12 of the magnetization of the magnetization pinned layer 12. For example, when the X-axis direction is the sensitivity axis, the first direction is a direction parallel to the X-axis direction. When the Y-axis direction is the sensitivity axis, the first direction is a direction parallel to the Y-axis direction. A direction different from the first direction and parallel to the XY plane may be referred to as a second direction. The second direction may be a direction orthogonal or substantially orthogonal to the first direction. In this case, for example, when the first direction is the X-axis direction, the second direction is the Y-axis direction, and when the first direction is the Y-axis direction, the second direction is a direction parallel to the X-axis direction.

Here, attention is focused on two MR elements 10 adjacent to each other in the first direction. Hereinafter, an interval between the two MR elements 10 arranged in the first direction may be referred to as an element interval L1 or simply L1 in some cases. In other words, L1 represents an interval between two MR elements 10 arranged in the direction of the sensitive axis of the MR element 10.

Here, attention is focused on two MR elements 10 adjacent to each other in the second direction. Hereinafter, an interval between the two MR elements 10 arranged in the second direction may be referred to as an element interval L2 or simply L2. In other words, L2 represents an interval between two MR elements 10 arranged in a direction different from the sensitive axis of the MR element 10. When the second direction is a direction orthogonal or substantially orthogonal to the first direction, L2 represents an interval between two MR elements 10 arranged in a direction orthogonal or substantially orthogonal to the sensitive axis of the MR element 10.

As shown in FIG. 2, an interval between two MR elements 10 that are adjacent to each other in the X-axis direction and arranged along the X-axis direction may be referred to as an element interval LX or simply LX. Similarly, an interval between two MR elements 10 that are adjacent to each other in the Y-axis direction and arranged along the Y-axis direction may be referred to as an element distance LY or simply as LY. For example, when the X-axis direction is the first direction and the Y-axis direction is the second direction, LX corresponds to L1 and LY corresponds to L2. For example, when the Y-axis direction is the first direction and the X-axis direction is the second direction, LY corresponds to L1 and LX corresponds to L2.

Note that, in the example embodiment, the interval between the two adjacent MR elements 10 may be represented by the shortest distance between an end of one of the two MR elements 10 and an end of the other of the two MR elements 10 in the direction in which the two MR elements 10 are arranged.

In an aspect, the magnetic sensor 1 is configured such that, for example, the interval L1 between the two MR elements 10 arranged in the first direction may be 0.5 times or more the dimension D of the MR elements 10. In this case, the relationship between L1 and D is expressed by the following relationship (1).

$$0.5 \times D \leq L 1 \qquad ( 1 )$$

Note that, as shown in FIG. 4, when the dimensions D of the two MR elements 10 arranged in the first direction are different from each other, a relatively large dimension D may be used as the dimension D in the above relational expression. The same may apply to other aspects described in the present specification. When Dmax denotes the maximum value of the dimensions D of the two MR elements 10 arranged in the first direction, the magnetic sensor 1 may be configured such that the interval L1 is 0.5 times Dmax or more. In this case, the relationship between L1 and Dmax is expressed by the following relationship (2).

$$0.5 \times D max \leq L 1 \qquad ( 2 )$$

For example, when the first direction is the X-axis direction and the second direction is the Y-axis direction, L1 in relationship (1) and relationship (2) may be replaced with LX. When the first direction is the Y-axis direction and the second direction is the X-axis direction, L1 in relationship (1) and relationship (2) may be replaced with LY.

In the example shown in FIG. 4, for example, for the MR elements 1004 and 1005 arranged in the Y-axis direction, the dimension D4 of the MR element 1004 is larger than the dimension D5 of the MR element 1005. In this case, D4>D5 is satisfied, and the interval LY1 between the MR elements 1004 and 1005 in the Y-axis direction may be configured to satisfy 0.5×D4≤LY1.

Similarly, in the example shown in FIG. 4, for example, for the MR elements 1005 and 1012 arranged in the Y-axis direction, the dimension D5 of the MR element 1005 is larger than the dimension D12 of the MR elements 1012. In this case, D5>D12 is satisfied, and the interval LY2 between the MR elements 1005 and 1012 in the Y-axis direction may be configured to satisfy 0.5×D5≤LY2.

Two MR elements 10 adjacent to each other in the first direction are spaced from each other by a distance larger than half the dimension D of each of the two MR elements 10, for example. When the element interval L1 in the first direction satisfies at least the relationship expressed by relationship (1) out of the relationship expressed by relationship (1) and the relationship expressed by relationship (2), the magnetic interactions that the two MR elements 10 adjacent to each other in the first direction affect each other can be reduced. As a result, the sensitivity to the magnetic field component parallel to the first direction of the target magnetic field, which is the magnetic field to be detected by each of the two MR elements 10 is suppressed from being varied. For example, when the first direction is the X-axis direction, the sensitivity to the magnetic field component MFx is suppressed from being varied.

In an aspect, the magnetic sensors 1 may be configured such that the element interval L1 in the first direction is 1.5 times or more the dimension D of the MR element 10. The relationship between L1 and D is expressed by the following relationship (3).

$$1.5 \times D \leq L 1 \qquad ( 3 )$$

For example, when the first direction is the X-axis direction, L1 in relationship (3) may be replaced with LX. When the element interval L1 in the first direction satisfies the relationship expressed by relationship (3), the magnetic interactions that affect each other between the MR elements 10 adjacent to each other in the first direction can be further reduced.

When the dimensions D of the plurality of MR elements 10 are substantially equal to each other, the element interval L1 in the first direction may be less than 1.9 times the dimensions D of the plurality of MR elements 10. In this case, the relationship between L1 and D is expressed by the following relationship (4).

$$L 1 < 1.9 \times D \qquad ( 4 )$$

For example, when the first direction is the X direction, L1 in relationship (4) may be replaced with LX. When the element interval L1 in the first direction satisfies the relationship of relationship (4), the area occupied by the plurality of MR elements 10 included in the magnetic sensor 1 (hereinafter, referred to as an occupied area, in some cases) can be reduced to twice or less the occupied area in a case where L1 is equal to 0.5 times the dimension D (L1=0.5×D).

For example, in a case of the aspect illustrated in FIGS. 1 to 3, the occupied area may be expressed as an area of the plurality of MR elements 10 arranged as a whole along the XY plane. Note that the phrase “the dimensions D of the plurality of MR elements 10 are substantially equal to each other” as used herein means that, for example, the dimensions D of the plurality of MR elements 10 fall within a range of about −5% to +5% around the average value. The deviation from the average value may be, for example, an intentional deviation or may be caused by a manufacturing error.

In a case where the dimensions D of the plurality of MR elements 10 are substantially equal to each other, the element interval L1 in the first direction may be 3.0 times or less the dimensions D of the plurality of MR elements 10, or less than 3.0 times the dimensions D of the plurality of MR elements 10. In this case, the relationship between L1 and D is expressed by the following relationships (5) and (6).

$$L 1 \leq 3. \times D \qquad ( 5 )$$

$$L 1 < 3. \times D \qquad ( 6 )$$

For example, when the first direction is the X-axis direction, L1 in relationships (5) and (6) may be replaced with LX. When the element interval L1 in the first direction satisfies the relationships expressed by relationships (5) and (6), noise caused by the plurality of MR elements 10 included in the magnetic sensor 1 can be suppressed to be approximately 2.5 times or less noise in a case where the element interval L1 is equal to 0.5 times the dimension D (L1=0.5×D). The element interval L1 may be less than 2.8 times (L1<2.8×D). In this case, the noise caused by the MR elements 10 can be suppressed to be twice or less of the noise in the case where the element interval L1 is equal to 0.5 times the dimension D (L1=0.5×D). The noise caused by the MR elements 10 includes, for example, noise caused by magnetization fluctuation, so-called 1/f noise, and the like.

In an aspect, the magnetic sensor 1 may be configured such that the element interval L1 in the first direction is larger than 0 and 0.5 times or less the dimension D of the MR elements 10. In this case, the relationship between L1 and D is expressed by the following relationship (7).

$$0 < L 1 \leq 0.5 \times D \qquad ( 7 )$$

For example, when the first direction is the X-axis direction, L1 in relationship (7) may be replaced with LX. When the element interval L1 in the first direction satisfies the relationship expressed by relationship (7), the magnetic sensor can enhance the sensitivity to the strength of the magnetic field component in the first direction (for example, MFx when the first direction is the X-axis direction).

When the element interval L1 between two MR elements 10 adjacent to each other in the first direction is less than 0.5 times the dimension D (L1<0.5×D), the sensitivity to the magnetic field component in the first direction varies in the increasing direction depending on the element interval L1. In contrast, for example, when the MR elements 10 are arranged such that the element interval L1 satisfies the relationship expressed by relationship (1), variation in the sensitivity to the magnetic field component in the first direction is sufficiently suppressed. In this case, for example, it is possible to suppress variation in sensitivity due to errors in the arrangement positions of the MR elements 10 in the magnetic sensor 1.

In a case of the aspect shown in FIG. 2, LX1 denotes the element interval in the X-axis direction between two MR elements 10 provided on the same lower electrodes 20, and LX2 denotes the element interval in the X-axis direction between two MR elements 10 provided on different lower electrodes 20. The element interval LX1 and the element interval LX2 may be equal to each other or may be different from each other. For example, relationship of LX1<LX2 may be satisfied. For example, when the first direction is the X-axis direction, LX1 may correspond to L1, and LX2 may correspond to L1. For example, when the second direction is the X-axis direction, LX1 may correspond to L2, and LX2 may correspond to the L2.

Furthermore, as shown in FIG. 3, the element interval L1 in the first direction between two MR elements 10 provided on the same lower electrodes 20 may be larger than the interval in the first direction between two lower electrodes 20 adjacent to each other in the first direction. In the configuration example of the magnetic sensor 1 shown in FIG. 3, a case is illustrated where the first direction is the X-axis direction. In the configuration example of the magnetic sensor 1 shown in FIG. 3, for example, the element interval LX11 in the X-axis direction between the MR elements 1001 and 1002 provided on the lower electrode 201 and the element interval LX12 in the X-axis direction between the MR elements 1003 and 1004 provided on the lower electrode 202 are larger than the element interval G20 in the X-axis direction between the lower electrodes 201 and 202 adjacent to each other in the X-axis direction.

The magnetic interactions between two MR elements 10 adjacent to each other in the first direction and the relationship between L1 and D have been mainly described above. The magnetic interactions act not only on two MR elements 10 adjacent to each other in the first direction but also on two MR elements 10 adjacent to each other in the second direction. The above description for the two MR elements 10 adjacent to each other in the first direction also applies to the two MR elements 10 adjacent to each other in the second direction. The description of the relationship between L1 and D also applies to the relationship between L2 and D. For example, in an aspect, the relationship between L2 and D may be represented by the following relationship (8).

$$0.5 \times D \leq L 2 \qquad ( 8 )$$

When Dmax denotes the maximum value of the dimensions D of the two MR elements 10 arranged in the first direction, the relationship between L2 and Dmax may be expressed by the following relationship (9).

$$0.5 \times D max \leq L 2 \qquad ( 9 )$$

In an aspect, the relationship between L2 and D may be represented by the following relationship (10).

$$1. 5 \times D \leq L 2 \qquad ( 10 )$$

In an aspect, the relationship between L2 and D may be represented by the following relationship (11).

$$L 2 < 1.9 \times D \qquad ( 11 )$$

In an embodiment, the relationship between L2 and D may be represented by the following relationship (12), relationship (13), or relationship (14).

$$L 2 \leq 3. \times D \qquad ( 12 )$$

$$L 2 < 3. \times D \qquad ( 13 )$$

$$L 2 < 2.8 \times D \qquad ( 14 )$$

In an aspect, the relationship between L2 and D may be represented by the following relationship (15).

$$0 < L 2 \leq 0.5 \times D \qquad ( 15 )$$

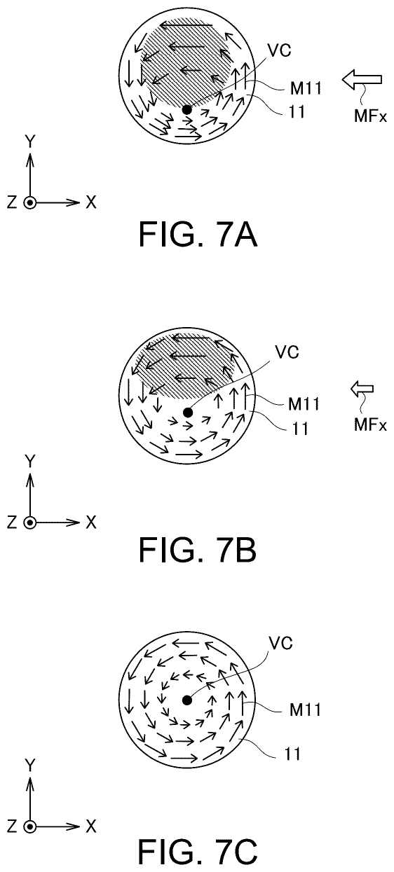

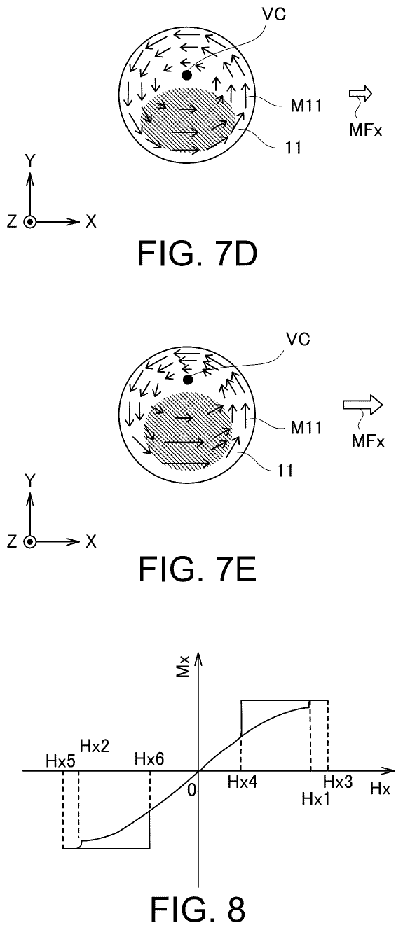

Next, with reference to FIG. 6 and FIGS. 7A to 7E, behavior of the MR element 10 is described. FIG. 6 is an explanatory diagram schematically showing the relationship between magnetic flux density B (horizontal axis) corresponding to the magnetic field component MFx parallel to the X-axis direction applied to the MR element 10 and a resistance value R (vertical axis) of the MR element 10 when a detection current is passed through the MR element 10 in the Z-axis direction. In other words, FIG. 6 is a diagram schematically showing the relationship between the resistance value R of the MR element 10 and the strength of the magnetic field component applied in the first direction, which is the sensitivity axis.

FIGS. 7A to 7E are plan views schematically showing the behavior of the free layer 11 of the MR element 10 when the magnetic field component MFx is applied, specifically, how the magnetic vortex structure M11 changes depending on the magnitude of the magnetic flux density B corresponding to the magnetic field component MFx applied to the MR element 10. In other words, FIGS. 7A to 7E are diagrams schematically illustrating the change of the magnetic vortex structure M11 depending on the magnitude of the magnetic flux density applied in the first direction being the sensitivity axis. Note that, in the free layer 11 illustrated in FIGS. 7A to 7E, the counterclockwise magnetic vortex structure M11 is formed when the free layer 11 is viewed in the −Z direction, but the clockwise magnetic vortex structure M11 may be formed. The following description applies to both cases.

FIG. 7A shows the magnetic vortex structure M11 when the flux density B=−B2 in the characteristic chart shown in FIG. 6. FIG. 7B shows the magnetic vortex structure M11 when the flux density B=−B1 in the characteristic chart shown in FIG. 6. FIG. 7C shows the magnetic vortex structure M11 when the flux density B=0 in the characteristic chart shown in FIG. 6. FIG. 7D shows the magnetic vortex structure M11 when the flux density B=B1 in the characteristic chart shown in FIG. 6. FIG. 7E shows the magnetic vortex structure M11 when the flux density B=B2 in the characteristic chart shown in FIG. 6. Note that the absolute values of B1 and −B1 are equal to each other. The absolute values of B2 and −B2 are equal to each other.

The lengths and orientations of white arrows shown in FIGS. 7A, 7B, 7D, and 7E represent strengths and orientations of the magnetic field components MFx applied to the MR element 10. The longer the length of the white arrow, the greater the strength of the magnetic field component MFx along the X-axis direction. FIGS. 7A and 7B show that the magnetic field components MFx are applied to the MR element 10 in the −X direction. FIGS. 7D and 7E show that the magnetic field components MFx are applied to the MR element 10 in the +X direction.

As shown in FIG. 6 and FIGS. 7A to 7E, the main magnetization direction component in the magnetic vortex structure M11 of the free layer 11 varies depending on the magnitude of the flux density B. In contrast, the direction M12 of the magnetization of the magnetization pinned layers 12 is not affected by the external magnetic field to be measured by the magnetic sensor 1, and is substantially fixed in a specific direction (for example, the +X direction). As shown in FIG. 6, the resistance value R of the MR element 10 is a resistance value R3 when the flux density B=0.

The resistance value R of the MR element 10 increases as an absolute value of the magnetic flux density B of the magnetic field component MFx in the −X direction increases, like the magnetic flux density B decreases from 0. The resistance value R of the MR element 10 is a resistance value R2 when the flux density B=−B1, and is a resistance value R1 when the flux density B=−B2. The resistance value R of the MR element 10 is eventually saturated at the maximum resistance value Rmax. This is because, when the magnetic field component MFx in the −X direction is applied, the magnetization component in the −X direction opposite to the +X direction, which is the direction M12 of the magnetization of the magnetization pinned layer 12, increases in the magnetic vortex structure M11.

Conversely, the resistance value R of the MR element 10 decreases as the absolute value of the magnetic flux density B of the magnetic field component MFx in the +X direction increases, like the magnetic flux density B increases from zero. The resistance value R of the MR element 10 is a resistance value R4 (<R3) when the flux density B=B1, and is a resistance value R5 (<R4) when the flux density B=B2. The resistance value R of the MR element 10 eventually saturates at the minimum resistance value Rmin. This is because, when the magnetic field component MFx in the +X direction is applied, the magnetization component in the +X direction the same as the +X direction, which is the direction M12 of the magnetization of the magnetization pinned layer 12, increases in the magnetic vortex structure M11.

Next, with reference to FIG. 8, a relationship between the strength of the magnetic field component MFx along the X-axis direction and the magnitude of the magnetization Mx of the entire free layer 11 will be described. Note that the magnitude of the magnetization Mx of the free layer 11 may be the magnitude of magnetic moment in the X-axis direction or may be the magnitude of a value having a correspondence with the magnetic moment in the X-axis direction. FIG. 8 is a characteristic chart schematically showing the relationship between the strength of the magnetic field component MFx along the X-axis direction and the magnitude of the magnetization of the entire free layer 11. In other words, FIG. 8 is a diagram schematically showing the relationship between the strength of the magnetic field component along the first direction and the magnitude of the magnetization of the entire free layer 11. In FIG. 8, the horizontal axis indicates the strength Hx of the magnetic field component MFx along the X-axis direction, and the vertical axis indicates the magnitude Mx of the magnetization of the entire free layer 11. In FIG. 8, the strength Hx when the direction of the magnetic field component MFx is the +X direction is expressed by a positive value, and the strength Hx when the direction of the magnetic field component MFx is the −X direction is expressed by a negative value.

When the direction of the magnetic field component MFx is the +X direction, the amount of the magnetization component oriented in the X direction increases in the magnetic vortex structure M11, and the magnitude Mx of the magnetization of the entire free layer 11 increases. When the direction of the magnetic field component MFx is the −X direction, the amount of the magnetization component oriented in the −X direction increases in the magnetic vortex structure M11, and the magnitude Mx of the magnetization of the entire free layer 11 decreases.

First, a case where the strength Hx increases from 0 by gradually increasing the magnetic field component MFx in the +X direction will be described. When the strength Hx is gradually increased from 0, the magnitude Mx of magnetization is gradually increased. When the strength Hx is equal to or greater than a value Hx1, the magnitude Mx of magnetization is constant, and the free layer 11 is saturated.

Next, a case where the strength Hx decreases from 0 by gradually increasing the magnetic field component MFx in the −X direction will be described. When the strength Hx gradually decreases from 0, the magnitude Mx of magnetization also gradually decreases. When the strength Hx is equal to or less than a value Hx2, the magnitude Mx of magnetization is constant, and the free layer 11 is saturated.

As shown in FIG. 8, within a range where the strength Hx is greater than the value Hx2, and is less than the value Hx1, the magnitude Mx of magnetization changes linearly with respect to the change of the strength Hx. Note that the expression “to linearly change” indicates that the magnitude Mx of magnetization changes linearly or substantially linearly with respect to the change of the strength Hx in the characteristic chart showing the relationship between the strength Hx and the magnitude Mx of magnetization.

In an example embodiment, for example, the MR element 10 may be configured such that the free layer 11 does not saturate when the strength Hx changes within a certain range. Furthermore, the MR element 10 may be configured such that the magnitude Mx of the magnetization of the free layer 11 linearly changes with respect to the change of the strength Hx in the range. Thereby, for example, the magnetic sensor 1 can provide an output that changes linearly with respect to the change of the strength Hx in a certain range.

When the strength Hx is greater than the value Hx1 and the free layer 11 is saturated, and thereafter the strength Hx is reduced from a value Hx3 greater than the value Hx1, there is less change in the magnitude Mx of magnetization until the strength Hx reaches a value Hx4 less than the value Hx1. When the strength Hx is less than the value Hx4, the magnitude Mx of magnetization linearly changes with respect to the change of the strength Hx similarly to a case in which the strength Hx changes within a certain range from the value Hx2 to the value Hx1.

Similarly, when the strength Hx is less than the value Hx2 and the free layer 11 is saturated, and thereafter the strength Hx decreases from a value Hx5 less than the value Hx2, there is less change in the magnitude Mx of magnetization until the strength Hx reaches a value Hx6 greater than the value Hx2. When the strength Hx is greater than the value Hx6, the magnitude Mx of magnetization linearly changes with respect to the change of the strength Hx similarly to a case in which the strength Hx changes within the certain range from the value Hx2 to the value Hx1.

Next, the relationship between the element interval L1 between two MR elements 10 arranged in the first direction being the sensitivity axis, and the sensitivity of the MR element 10 to magnetic field component will be described. When the plurality of MR elements 10 are arranged close to each other in the XY plane as in the magnetic sensor 1, the state of the magnetic vortex structure M11 of the free layer 11 shown in FIGS. 7A to 7E may vary depending on the magnitude of the interval between the plurality of MR elements 10. When the state of the magnetic vortex structure M11 of the free layer 11 varies even though the same magnetic field is applied to the MR element 10, the relationship between the magnetic vortex structure M11 of the free layer 11 and the direction M12 of the magnetization of the magnetization pinned layers 12 varies, and as a result, the sensitivities of the plurality of MR elements 10 vary.

Hereinafter, a case where the first direction being the sensitivity axis is the X-axis direction will be described as an example. In this case, the element interval LX in the X-axis direction corresponds to the element interval L1 in the first direction, and the Y-axis direction corresponds to the second direction. In this case, the Y-axis direction is also referred to as an other-axis direction. In this case, the sensitivity of the MR element 10 to the magnetic field component MFx is also referred to as main-axis sensitivity, and the sensitivity of the MR element 10 to the magnetic field component MFy is also referred to as other-axis sensitivity.

The following description is based on sensitivity obtained by simulation. In the simulation, the following first relationship and second relationship are obtained. The first relationship is a relationship between the element interval LX and the sensitivity (other-axis sensitivity) of the MR element 10 to the magnetic field component MFy when the magnetic field component MFy along the Y-axis direction, which is the other-axis direction, is applied to two MR elements 10 arranged along the X-axis direction. The second relationship is a relationship between the element interval LX and the sensitivity (main-axis sensitivity) of the MR element 10 to the magnetic field component MFx when the magnetic field component MFx along the X-axis direction, which is the sensitivity axis direction, is applied to the two MR elements 10 arranged along the X-axis direction.

In the simulation, the two MR elements 10 have the same structure. The dimension D of each of the two MR elements 10 is 1.0 μm. The sensitivity of each of the two MR elements 10 is obtained. Note that in the simulation, a numerical value (LX/D) normalized by setting the dimension D to 1 is used for the element interval LX.

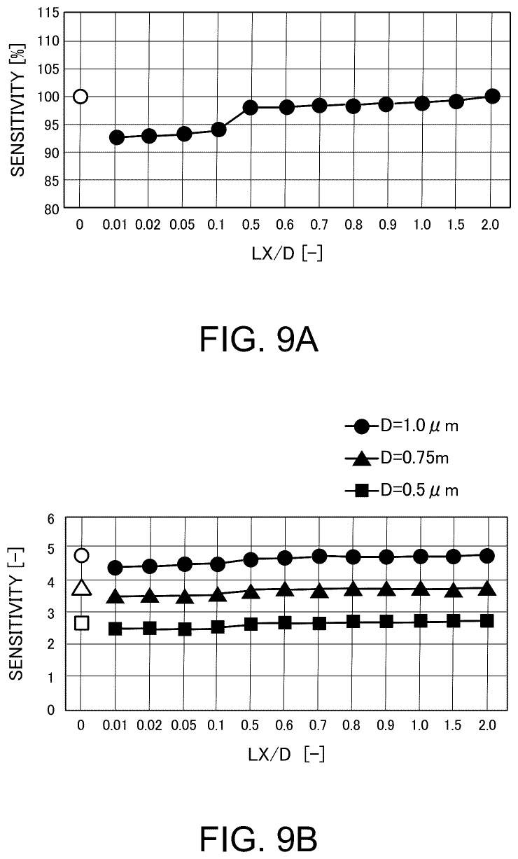

FIG. 9A is a characteristic chart showing the relationship between the normalized element interval LX and the sensitivity (other-axis sensitivity) of the MR element 10 to the magnetic field component MFy. In FIG. 9A, the horizontal axis represents LX/D, and the vertical axis represents the sensitivity of the MR element 10 to the magnetic field component MFy. Note that the vertical axis represents a numerical value % normalized with the sensitivity when the magnetic field component MFy of a specific magnitude is applied to one MR element 10 being 100%. Hereinafter, for convenience of description, the sensitivity corresponding to 100% may be referred to as a first reference sensitivity. In FIG. 9A, an open dot at the position of LX/D=0 on the horizontal axis represents the sensitivity of the single MR element 10 to the magnetic field component MFy.

As shown in FIG. 9A, when LX/D is less than 0.5, the sensitivity decreases and changes by 5% or more as compared with the first reference sensitivity. When LX/D is 0.5 or more, the sensitivity decreases and changes by about 2% or less as compared with the first reference sensitivity. When LX/D is 1.5 or more, the sensitivity is equivalent to the first reference sensitivity.

In other words, when the element interval LX is less than 0.5 times the dimension D (LX<0.5×D), the other-axis sensitivity is reduced. When the element interval LX is within a range of 0.5 times or more and 1.5 times or less (0.5×D≤LX≤1.5×D), the variation (dispersion) of the other-axis sensitivity is suppressed to about 2%. When the element interval LX is within a range of 1.5 times or more the dimension D (1.5×D≤LX), the variation in the other-axis sensitivity is further suppressed.

From the above tendency, it can be understood that the variation in the other-axis sensitivity, which is the sensitivity to the magnetic field component MFy applied from the Y-axis direction different from the sensitivity axis, is reduced by adjusting the element interval LX between the plurality of MR elements 10 adjacent to each other in the X-axis direction, which is the direction of the sensitivity axis. Note that this tendency can be seen even when the dimension D of each of the two MR elements 10 is other than 1.0 μm as shown in FIG. 9B, for example, when the dimension D is 0.5 μm to 2.0 μm. It can be seen from FIG. 9B that a specific relationship is established between a value of the dimension D and a value of the element interval LX and the sensitivity to the magnetic field component MFy in the Y-axis direction, regardless of the magnitude of the dimension D.

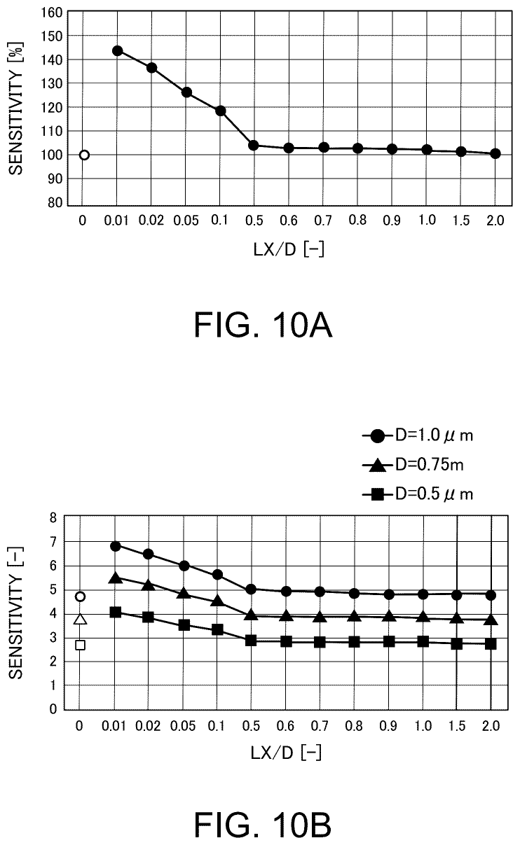

FIG. 10A is a characteristic chart showing the relationship between the normalized element interval LX and the sensitivity (main-axis sensitivity) of the MR element 10 to the magnetic field component MFx. In FIG. 10A, the horizontal axis represents LX/D, and the vertical axis represents the sensitivity of the MR element 10 to the magnetic field component MFx. Note that the vertical axis represents a numerical value % normalized with the sensitivity when the magnetic field component MFx of a specific magnitude is applied to one MR element 10 being 100%. Hereinafter, for convenience of description, the sensitivity corresponding to 100% may be referred to as a second reference sensitivity. In FIG. 10A, the white dot at the position of the element interval LX=0 on the horizontal axis indicates the sensitivity of the single MR element 10 to the magnetic field component MFx.

As shown in FIG. 10A, when LX/D is less than 0.5, the sensitivity increases and changes by about 10% to 50% as compared with the second reference sensitivity. When LX/D is 0.5 or more, the sensitivity increases and changes by about 2% or less as compared with the second reference sensitivity. When LX/D is 1.5 or more, the sensitivity is equivalent to the second reference sensitivity.

In other words, when the element interval LX is within a range of 0.5 times or more and 1.5 times or less (0.5×D≤LX≤1.5×D), the variation (dispersion) of the main-axis sensitivity is suppressed to about 2%. When the element interval LX is within a range of 1.5 times or more the dimension D (1.5×D≤LX), the variation in the main-axis sensitivity is further suppressed.

From the above tendency, it can be understood that the variation in the main-axis sensitivity, which is the sensitivity to the magnetic field component MFx applied from the X-axis direction being the sensitivity axis, is reduced by adjusting the element interval LX between the plurality of MR elements 10 adjacent to each other in the X-axis direction, which is the direction of the sensitivity axis. Note that this tendency can be seen even when the dimension D of each of the two MR elements 10 is other than 1.0 μm as shown in FIG. 10B, for example, when the dimension D is 0.5 μm to 2.0 μm. It can be seen from FIG. 10B that a specific relationship is established between a value of the dimension D and a value of the element interval LX and the sensitivity to the magnetic field component MFx in the Y-axis direction, regardless of the magnitude of the dimension D.

As described above, the sensitivity (other-axis sensitivity) to magnetic field component applied from the second direction different from the sensitive axis can be adjusted by adjusting the element interval L1 between the plurality of MR elements 10 adjacent to each other in the first direction, which is the direction of the sensitivity axis. For example, when the element interval L1 is within a range of 0.5 times or more and 1.5 times or less (0.5×D≤L1≤1.5×D), the variation (dispersion) of the other-axis sensitivity is suppressed to about 2%. When the element interval L1 is within a range of 1.5 times or more the dimension D (1.5×D≤L1), the variation in the other-axis sensitivity is further suppressed.

Similarly, the sensitivity (main-axis sensitivity) to the magnetic field component applied from the sensitivity-axis direction can be adjusted by adjusting the element interval L1 between the plurality of MR elements 10 adjacent to each other in the first direction, which is the direction of the sensitivity axis. For example, when the element interval L1 is within a range of 0.5 times or more and 1.5 times or less (0.5×D≤L1≤1.5×D), the variation (dispersion) of the main-axis sensitivity is suppressed to about 2%. When the element interval L1 is within a range of 1.5 times or more the dimension D (1.5×D≤L1), the variation in the main-axis sensitivity is further suppressed.

Since the free layer 11 of the MR element 10 has the magnetic vortex structure M11, the sensitivity to magnetic field in a specific direction (first direction) and the sensitivity to magnetic field in a direction (for example, a second direction perpendicular to the direction of sensitivity axis) different from the specific direction vary depending on a distance between two MR elements 10 adjacent to each other in the specific direction of the sensitivity axis (first direction). In the specific examples illustrated in FIGS. 9A, 9B, 10A, and 10B, the first direction is the X-axis direction. However, the disclosure is not limited to this, and similar tendency is obtained even when the first direction is a direction other than the X-axis direction (for example, the Y-axis direction). For example, when two MR elements 10 are arranged in the Y-axis direction, the Y-axis direction is defined as the first direction, and LX/D indicated by the horizontal axis in each of FIGS. 9A, 9B, 10A, and 10B is read as LY/D. In this case, LY corresponds to L1.

The change in the state of the magnetic vortex structure M11 of the free layer 11 and the change in the relationship between the magnetic vortex structure M11 of the free layer 11 and the direction M12 of magnetization of the magnetization pinned layer 12 may occur, not only in a case where the element interval L1 in the main axis direction is changed, but also in a case where the element interval (for example, element interval L2) in a direction other than the main axis direction is changed. For example, the sensitivity to a magnetic field in the second direction and the sensitivity to a magnetic field in a direction different from the second direction (for example, the first direction that is the direction of the sensitivity axis) vary depending on the distance between two MR elements 10 adjacent to each other in the second direction. Therefore, by adjusting the element interval L2 between the plurality of MR elements 10 adjacent to each other in the second direction different from the direction of the sensitivity axis, the sensitivity (main-axis sensitivity) to the magnetic field component applied from the direction of the sensitivity axis can be adjusted. For example, when the element interval L2 is within a range of 0.5 times or more and 1.5 times or less (0.5×D≤L2≤1.5×D), the variation (dispersion) of the main-axis sensitivity is suppressed. When the element interval L2 is within a range of 1.5 times or more the dimension D (1.5×D≤L2), the variation in the main-axis sensitivity is further suppressed.

Similarly, by adjusting the element interval L2 between the plurality of MR elements 10 adjacent to each other in the second direction different from the direction of the sensitivity axis, the sensitivity (other-axis sensitivity) to magnetic field component applied from the second direction different from the sensitivity axis can be adjusted. For example, when the element interval L2 is within a range of 0.5 times or more and 1.5 times or less (0.5×D≤L2≤1.5×D), the variation (dispersion) of the other-axis sensitivity is suppressed. When the element interval L2 is within a range of 1.5 times or more the dimension D (1.5×D≤L2), the variation in the other-axis sensitivity is further suppressed.

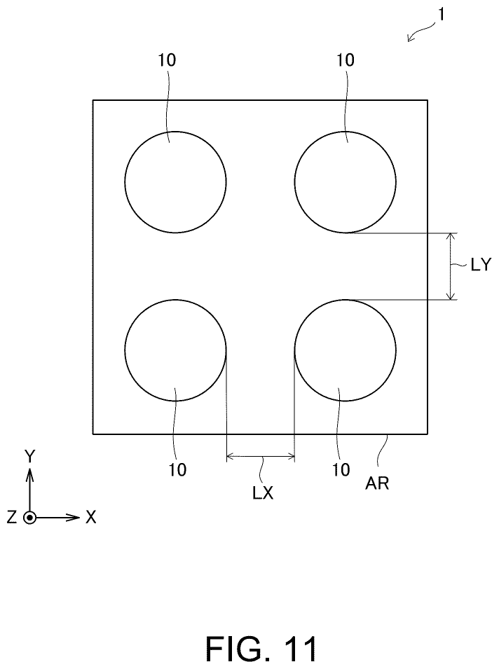

Next, as a specific example, as shown in FIG. 11, a region. AR of a part of the magnetic sensor 1 is considered. The region AR includes four MR elements 10 arranged in a matrix of two columns in the X-axis direction and two rows in the Y-axis direction. FIG. 11 is a schematic diagram showing a partial region AR of the magnetic sensor 1 in an enlarged manner. In the example shown in FIG. 11, the first direction, which is the direction of the sensitivity axis, is the X-axis direction.

Hereinafter, for convenience of description, the four MR elements 10 arranged in a matrix will be referred to as a first MR element 10, a second MR element 10, a third MR element 10, and a fourth MR element 10 to distinguish the four MR elements 10 from one another. The first MR element 10 and the second MR element 10 are adjacent to each other with the element interval LX in the X-axis direction. The third MR element 10 and the fourth MR element 10 are adjacent to each other with the element interval LX in the X-axis direction. The first MR element 10 and the third MR element 10 are adjacent to each other with the element interval LY in the Y-axis direction. The second MR element 10 and the fourth MR element 10 are adjacent to each other with the element interval LY in the Y-axis direction.

For example, when the element interval LX between the first MR element 10 and the second MR element 10 in the X-axis direction is less than 0.5 times the dimension D, the sensitivity (the main-axis sensitivity) of each of the first MR element 10 and the second MR element 10 to the magnetic field component MFx in the X-axis direction can be increased. In this case, the sensitivity (other-axis sensitivity) of each of the first MR element 10 and the second MR element 10 to the magnetic field component MFy in the Y direction can be reduced. Similarly, when the element interval LX between the third MR element 10 and the fourth MR element 10 in the X-axis direction is less than 0.5 times the dimension D, the sensitivity (the main-axis sensitivity) of each of the third MR element 10 and the fourth MR element 10 to the magnetic field component MFx in the X-axis direction can be increased. In this case, the sensitivity (other-axis sensitivity) of each of the third MR element 10 and the fourth MR element 10 to the magnetic field component MFy in the Y direction can be reduced.

When the element interval LY between the first MR element 10 and the third MR element 10 in the Y-axis direction is less than 0.5 times the dimension D, one of the sensitivity (the main-axis sensitivity) of each of the first MR element 10 and the third MR element 10 to the magnetic field component MFx in the X-axis direction and the sensitivity (the other-axis sensitivity) of each of the first MR element 10 and the third MR element 10 to the magnetic field component MFy in the Y-axis direction can be increased, and the other can be reduced. Similarly, when the element interval LY between the second MR element 10 and the fourth MR element 10 in the Y-axis direction is less than 0.5 times the dimension D, one of the sensitivity (the main-axis sensitivity) of each of the second MR element 10 and the fourth MR element 10 to the magnetic field component MFx in the X-axis direction and the sensitivity (the other-axis sensitivity) of each of the second MR element 10 and the fourth MR element 10 to the magnetic field component MFy in the Y-axis direction can be increased, and the other can be reduced.

For example, when the element interval LX between the first MR element 10 and the second MR element 10 in the X-axis direction is 0.5 times or more or 1.5 times or more the dimension D, the variation in the main-axis sensitivity of each of the first MR element 10 and the second MR element 10 can be suppressed, and the variation in the other-axis sensitivity of each of the first MR element 10 and the second MR element 10 can be suppressed. Similarly, when the element interval LX between the third MR element 10 and the fourth MR element 10 in the X-axis direction is 0.5 times or more or 1.5 times or more the dimension D, the variation in the main-axis sensitivity of each of the third MR element 10 and the fourth MR element 10 and the variation in the other-axis sensitivity of each of the third MR element 10 and the fourth MR element 10 can be suppressed.

When the element interval LY between the first MR element 10 and the third MR element 10 in the Y-axis direction is 0.5 times or more or 1.5 times or more the dimension D, the variation in the main-axis sensitivity of each of the first MR element 10 and the third MR element 10 can be suppressed, and the variation in the other-axis sensitivity of each of the first MR element 10 and the third MR element 10 can be suppressed. Similarly, when the element interval LY between the second MR element 10 and the fourth MR element 10 in the Y-axis direction is 0.5 times or more or 1.5 times or more the dimension D, the variation in the main-axis sensitivity of each of the second MR element 10 and the fourth MR element 10 and the variation in the other-axis sensitivity of each of the second MR element 10 and the fourth MR element 10 can be suppressed.

Note that although the four MR elements 10 are provided in the region AR in the example shown in FIG. 11, the above description also applies to a case where a plurality of MR elements 10 arranged in a matrix of three or more columns in the X-axis direction and three or more rows in the Y-axis direction are provided in the region AR. The element interval LX in the X-axis direction and the element interval LY in the Y-axis direction may be defined independently, or may be defined based on a specific relationship. The element interval LX and the element interval LY may be equal to each other or may be different from each other.

For example, by making the element interval LX and the element interval LY different from each other, the effect produced between two MR elements 10 arranged in the X-axis direction and the effect produced between two MR elements 10 arranged in the Y-axis direction can be made different from each other. In one example, the element interval LY may be larger than the element interval LX (LY>LX). In this case, the dimension AY of the region AR in the Y-axis direction is larger than the dimension AX of the region AR in the X-axis direction (AY>AX).

By arranging the plurality of MR elements 10 so as to satisfy LY>LX and AY>AX, for example, it is possible to suppress the variation in the other-axis sensitivity of the MR element 10 while increasing the main-axis sensitivity of the MR element 10. When attention is paid to a certain single MR element 10, by making the element interval LX relatively small, the direction of a part of the component of the magnetic field component MFy in the Y-axis direction that is applied to the certain MR element 10 when it is assumed that only the certain single MR element 10 is present may change toward another MR element 10 adjacent to the certain single MR element 10 in the X-axis direction. This reduces the other-axis sensitivity of the MR element 10. By relatively increasing the element interval LY, it is possible to prevent the direction of a part of the component of the magnetic field component MFx in the X-axis direction that is applied to the single MR element 10 when it is assumed that only the single MR element 10 is present from changing toward another MR element 10 adjacent to the single MR element 10 in the Y-axis direction. This makes it possible to suppress a decrease in the main-axis sensitivity of the MR element 10.

The relationship between LX and LY can be expressed as L2>L1, by using the element interval L1 in the first direction and the element interval L2 in the second direction. Similarly, the relationship between AX and AY can be expressed as A2>A1, by using the dimension A1 of the region AR in the first direction and the dimension A2 of the region AR in the second direction. The plurality of MR elements 10 may be arranged so as to satisfy L2>L1 and A2>A1.

Next, the occupied area, which is the area in which the plurality of MR elements 10 included in the magnetic sensor 1 are arranged, will be described based on the region AR shown in FIG. 11. The occupied area is defined as an area along the XY plane. Here, the relationship between the element intervals LY and LX and the occupied area is obtained by simulation. In the simulation, the four MR elements 10 have the same structure. In the simulation, numerical values (LY/D, LX/D) obtained by normalizing the element intervals LX and LY with the dimension D as 1 are used. When LY/D and LX/D are 1, the dimension D of each MR element 10, the element interval LY between two MR elements 10 adjacent to each other in the Y-axis direction, and the element interval LX between two MR elements 10 adjacent to each other in the X-axis direction are equal to each other.

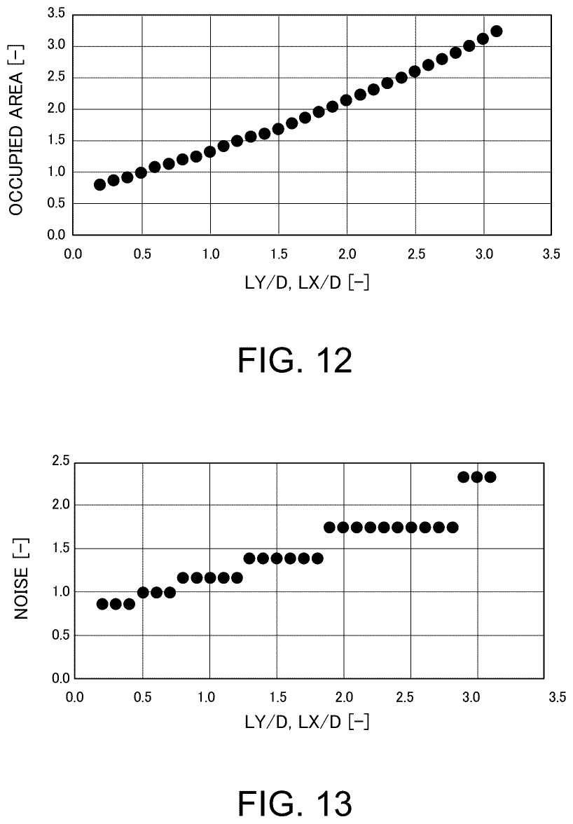

FIG. 12 is a characteristic chart showing the relationship between the normalized element intervals LX and LY and the occupied area. In FIG. 12, the horizontal axis represents LY/D and LX/D, and the vertical axis represents the occupied area. The vertical axis indicates a numerical value normalized by setting the value of the occupied area when LY/D and LX/D are 0.5 as 1. Hereinafter, the occupied area when LY/D and LX/D are 0.5 may be referred to as a first reference area for convenience.

As illustrated in FIG. 12, when each of LY/D and LX/D is 3.0, the occupied area is approximately three times the first reference area. When each of LY/D and LX/D is 2.0, the occupied area is approximately twice the first reference area. When each of LY/D and LX/D is less than 1.9, the occupied area is approximately twice or less the first reference area. When each of LY/D and LX/D is 1.0 or less, the occupied area is approximately 1.5 times or less the first reference area.

In other words, when the element intervals LY and LX are each set to be equal to or less than three times the dimension D of the MR element 10 (LY≤3.0×D, LX≤3.0×D), the occupied area can be suppressed to about three times the first reference area. When the element intervals LY and LX are each set to be less than 2.0 times the dimension D of the MR element 10 (LY<2.0×D, LX<2.0×D), the occupied area can be suppressed to about twice the first reference area. When the element intervals LY and LX are each set to less than 1.9 times the dimension D of the MR element 10 (LY<1.9×D, LX<1.9×D), the occupied area can be suppressed to about twice or less the first reference area. When the element intervals LY and LX are each set to be 1.0 times or less the dimension D of the MR element 10 (LY, LX≤1.0×D), the occupied area can be suppressed to about 1.5 times or less the first reference area.

From the results shown in FIG. 12, for example, the element interval between the MR elements 10 adjacent to each other in the first direction (for example, the X-axis direction) and the element interval between the MR elements 10 adjacent to each other in the second direction (for example, the Y-axis direction) may be adjusted so that the entire magnetic sensor 1 is formed to have an appropriate size while adjusting the variation in sensitivity in the first direction, in accordance with the specifications required for the magnetic sensor 1, or the like. Note that the element intervals LY and LX may be equal to each other or may be different from each other. For example, the element interval LY may be 0.8 times the dimension D of the MR element 10, and the element interval LX may be 1.2 times the dimension D of the MR element 10.

Next, the relationship between the element intervals LY and LX and noise of the magnetic sensor 1 will be described. It is known that, when the MR element 10 is a TMR element, noise of the magnetic sensor 1 can be reduced by connecting a plurality of MR elements 10 in series or in parallel (for example, connecting the MR elements 10 in an array). When the area of a region in which the MR elements 10 can be arranged (for example, the area of a substrate on which the elements are arranged) is determined in the magnetic sensor 1, the element intervals LY and LX affect the total number of the MR elements 10 included in the magnetic sensor 1. For example, when the dimension D of the MR element 10 is a specific size, the number of elements that can be arranged in a certain area decreases as the element intervals LY and LX increase. In this case, the noise of the magnetic sensor 1 tends to increase. On the other hand, when the element intervals LY and LX decrease, the number of elements that can be arranged in a certain area increases. In this case, the noise of the magnetic sensor 1 tends to decrease.

Here, the relationship between the element intervals LY and LX and the noise generated in the four MR elements 10 in the region AR of a part of the magnetic sensor 1 shown in FIG. 11 is determined by simulation. The conditions of this simulation are the same as the conditions of the simulation for obtaining the relationship between the element intervals LY and LX and the occupied area.

FIG. 13 is a characteristic chart showing the relationship between the normalized element intervals LX and LY and noise. In FIG. 13, the horizontal axis represents LY/D and LX/D, and the vertical axis represents noise. Note that the vertical axis represents a numerical value normalized by setting the value of noise when LY/D and LX/D are 0.5 as 1. Hereinafter, the noise when LY/D and LX/D are 0.5 may be referred to as first reference noise for convenience.

In the simulation, the dimension D of the MR element 10 and the area in which the MR element 10 can be arranged are kept constant, and thus, when the element intervals LY and LX are changed, the number of elements that can be arranged in a certain area changes gradually and in a stepwise manner. More specifically, in the simulation illustrated in FIG. 13, as the element intervals LY and LX increase, the number of MR elements 10 that can be arranged in a certain area decreases stepwise. The simulation illustrated in FIG. 13 shows that the noise increases in steps.

As illustrated in FIG. 13, when each of LY/D and LX/D is 3.0, the noise is approximately 2.5 times the first reference noise. When each of LY/D and LX/D is 2.8, the noise is approximately twice the first reference noise. When each of LY/D and LX/D is 1.0, the noise is approximately 1.5 times the first reference noise. When each of LY/D and LX/D is 0.5, the noise is approximately 1.0 times the first reference noise.

In other words, when each of the element intervals LY and LX is set to less than 3.0 times the dimension D of the MR element 10 (LY<3.0×D, LX<3.0×D), the noise can be suppressed to be approximately 2.5 times or less the first reference noise. When each of the element intervals LY and LX is set to less than 2.8 times the dimension D of the MR element 10 (LY<2.8×D, LX<2.8×D), the noise can be suppressed to twice or less the first reference noise. When each of the element intervals LY and LX are set to about 1.0 times the dimension D of the MR element 10 (for example, 0.8×D<LY and LX<1.2×D), the noise can be suppressed to 1.5 times or less the first reference noise. When the element intervals LY and LX are each set to 0.5 times or less the dimension D of the MR element 10 (LY≤0.5×D, LX≤0.5×D), the noise generated in the four MR elements 10 can be suppressed to 1.0 times or less the first reference noise at the maximum.

From the results shown in FIG. 13, for example, the element intervals of the MR elements 10 arranged in a specific direction (for example, the X-axis direction) may be adjusted so as to appropriately suppress noise included in the output of the magnetic sensor 1 while adjusting the variation in sensitivity in the specific direction in accordance with the specifications required for the magnetic sensor 1, or the like.

Since the magnetic sensor 1 includes the plurality of MR elements 10, the sensitivity of the magnetic field components in the first direction or the second direction and the variation thereof can be adjusted by appropriately adjusting the interval L1 between the elements arranged in the first direction being the sensitivity axis and the interval L2 between the elements arranged in the second direction. For example, when the X-axis direction is defined as a first direction and the Y-axis direction is defined as a second direction, the sensitivity to the magnetic field component in the X-axis direction or the Y-axis direction and the variation thereof can be appropriately adjusted, by appropriately adjusting the element interval LX in the X-axis direction and the element interval LY in the Y-axis direction orthogonal to the X-axis direction.

To be specific, the element interval LX in the X-axis direction corresponding to the element interval L1 may be, for example, 0.5 times or less the dimension D of each of the plurality of MR elements 10. When each of the plurality of MR elements 10 satisfies the relationship of 0<LX≤0.5×D (0<L1≤0.5×D), the MR elements 10 are highly sensitive to the magnetic field component MFx in the X-axis direction.

In the magnetic sensor 1, the element interval LX in the X-axis direction corresponding to the element interval L1, may be 0.5 times or more the dimension D of each of the plurality of MR elements 10 (0.5×D≤LX). In this case, it is possible to reduce the magnetic interaction that affects the MR elements 10 adjacent to each other in the X-axis direction. As a result, the change in the sensitivity of each of the plurality of MR elements 10 can be suppressed. In particular, when the element interval LX is 1.5 times or more the dimension D of each of the plurality of MR elements 10 (1.5×D≤LX), the magnetic interaction between the plurality of MR elements 10 adjacent to each other in the X-axis direction can be further reduced, and the change in sensitivity can be further suppressed.

The element interval LY in the Y-axis direction corresponding to the element interval L2 may be, for example, 0.5 times or more the dimension D of each of the plurality of MR elements 10. When each of the plurality of MR elements 10 satisfies the relationship 0.5×D≤LY (0.5×D≤L2), it is possible to reduce magnetic interactions that affect each other between the plurality of MR elements 10 adjacent to each other in the Y-axis direction. As a result, the change in the sensitivity of each of the plurality of MR elements 10 can be suppressed. In particular, when the element interval LY is 1.5 times or more the dimension D (1.5×D≤LY), the magnetic interaction that the plurality of MR elements 10 adjacent to each other in the Y-axis direction affect each other can be further reduced, and the change in sensitivity can be further suppressed.

### Second Example Embodiment

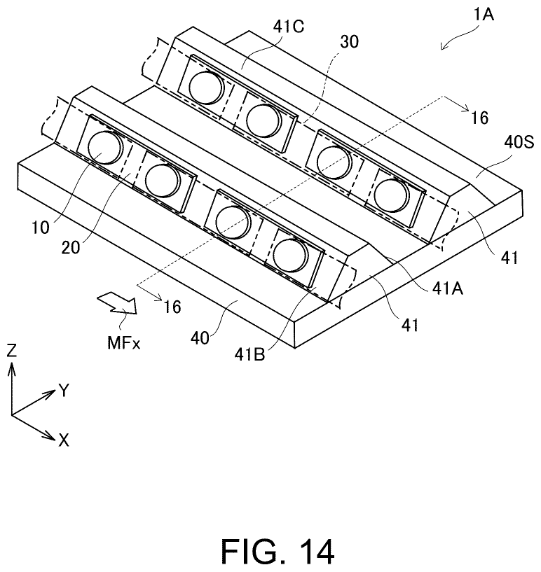

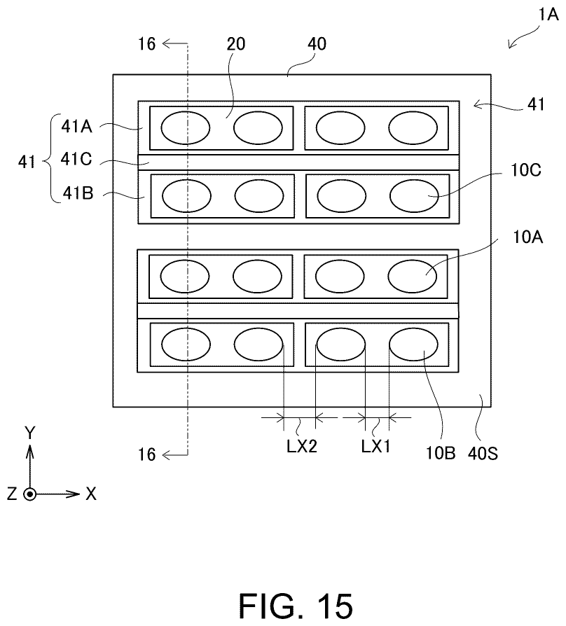

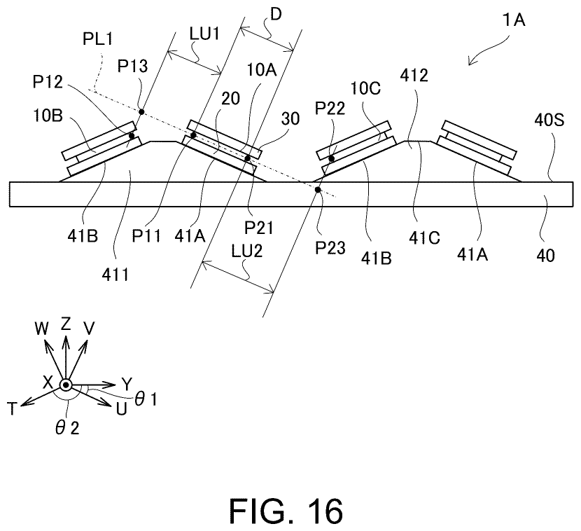

First, with reference to FIGS. 14, 15, and 16, a configuration of a magnetic sensor 1A according to a second example embodiment of the disclosure is described. The magnetic sensor 1A corresponds to a specific example of the magnetic sensor according to one aspect of the disclosure. FIG. 14 is a perspective view schematically showing a configuration example of an appearance of the magnetic sensor 1A. FIG. 15 is a plan view showing a planar configuration example of the magnetic sensor 1A. FIG. 16 is a cross-sectional view showing a cross-sectional configuration example of the magnetic sensor 1A. Note that FIG. 16 illustrates a cross section taken along line 16-16 shown in FIGS. 14 and 15.

In the magnetic sensor 1A, a stacking plane of each of the plurality of MR elements 10 is inclined with respect to an XY plane parallel to an X-axis direction and a Y-axis direction in which a plurality of MR elements 10 are arranged. The stacking direction of the MR element 10 is a direction inclined with respect to a Z-axis direction orthogonal to the XY plane. The magnetic sensor 1A is configured to be able to detect, for example, a magnetic field parallel to the Z-axis direction and a magnetic field parallel to the Y-axis direction. In this case, at least some of the MR elements 10 are arranged on an inclined surface that is inclined with respect to the XY plane. The direction of a sensitivity axis of the MR element 10 arranged on the inclined surface may be set to any direction parallel to the inclined surface, for example.

The magnetic sensor 1A includes, for example, a substrate 40, a plurality of protrusions 41, a plurality of MR elements 10, a plurality of lower electrodes 20, and a plurality of upper electrodes 30. Note that for convenience of description, the plurality of upper electrodes 30 are indicated by a two dot chain line in FIG. 14, and the upper electrodes 30 are not illustrated in FIG. 15. The substrate 40 may include a flat surface 40S parallel to the XY plane, for example. In this case, the flat surface 40S is parallel to the reference plane. The thickness direction of the substrate 40 is a direction orthogonal to the flat surface 40S, and is the Z-axis direction in an aspect of FIG. 16.

The plurality of protrusions 41 are formed to protrude from the flat surface 40S in the thickness direction of the substrate 40. The plurality of protrusions 41 are arranged on the flat surface 40S of the substrate 40 so as to be spaced apart from each other. The plurality of protrusions 41 are arranged to be adjacent to each other in the Y-axis direction, for example. Hereinafter, a certain protrusion 41 included in the plurality of protrusions 41 may be simply referred to as a protrusion 41.

The protrusion 41 includes, for example, a first inclined surface 41A and a second inclined surface 41B each extending in the X-axis direction. The protrusion 41 may further include a top surface 41C. In a case where the protrusion 41 includes the top surface 41C, the cross-section of the protrusion 41 parallel to the YZ plane orthogonal to an extending direction has, for example, a substantially trapezoidal shape as shown in FIG. 16. Note that the protrusion 41 is not limited to this, and may be formed such that the cross section parallel to the YZ plane has a substantially triangular shape without including the top surface 41C. The protrusion 41 may be formed in a shape in which a cross section parallel to the YZ plane has a curved surface gently protruding in the +Z direction. In this case, the first inclined surface 41A and the second inclined surface 41B may be formed as a part of the curved surface.

Note that, in the description of the example embodiment, a direction in which the protrusion 41 protrudes from the substrate 40 is defined as a +Z direction, and a direction opposite thereto is defined as a −Z direction. A T direction, a U direction, a V direction, and a W direction illustrated in FIG. 16 are defined as follows. The U direction is a direction rotated from the +Y direction toward the −Z direction about the X axis as a rotation center, and is orthogonal to the X axis. An angle θ1 formed by the U direction and the +Y direction is larger than 0 degrees and smaller than 90 degrees. The T direction is a direction rotated from the −Y direction toward the −Z direction about the X axis as the rotation center, and is orthogonal to the X axis. An angle θ2 formed by the T direction and the +Y direction is larger than 90 degrees and smaller than 180 degrees.

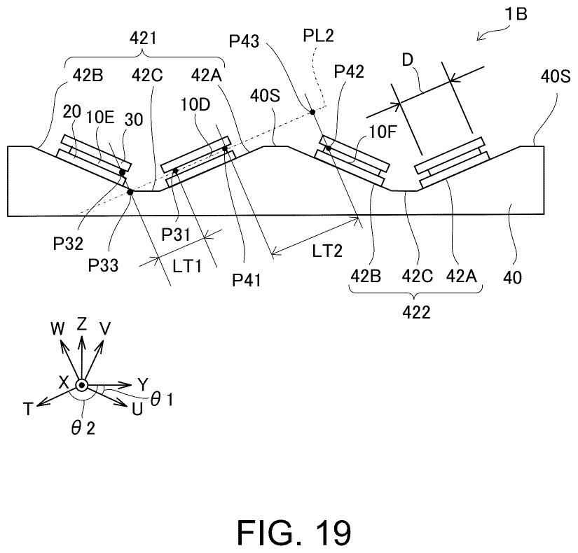

The V direction is a direction rotated from the +Y direction toward the +Z direction about the X axis as the rotation center, and is orthogonal to both the U direction and the X direction. The W direction is a direction rotated from the −Y direction toward the +Z direction about the X axis as the rotation center, and is orthogonal to both the T direction and the X direction. Note that a T direction, a U direction, a V direction, and a W direction shown in FIG. 19 described below are defined similarly to the T direction, the U direction, the V direction, and the W direction shown in FIG. 16.

The opposite directions to the T, U, V, and W directions will be referred to as −T, −U, −V, and −W directions, respectively. For convenience of description, the T, U, V, and W directions are also referred to as +T, +U, +V, and +W directions, respectively.

Hereinafter, an axis parallel to the +T direction or the −T direction is referred to as a T axis. A direction parallel to the +T direction or the −T direction is referred to as a T-axis direction. An axis parallel to the +U direction or the −U direction is referred to as a U axis. A direction parallel to the +U direction or the −U direction is referred to as a U-axis direction. An axis parallel to the +V direction or the −V direction is referred to as a V axis. A direction parallel to the +V direction or the −V direction is referred to as a V-axis direction. An axis parallel to the +W direction or the −W direction is referred to as a W axis. A direction parallel to the +W direction or the −W direction is referred to as a W-axis direction.

The first inclined surface 41A is a flat surface parallel to both the U-axis and the X-axis. The normal line of the first inclined surface 41A is parallel to the V-axis. The second inclined surface 41B is a flat surface parallel to both the T-axis and the X-axis. The normal line of the second inclined surface 41B is parallel to the W-axis. The first inclined surface 41A and the second inclined surface 41B are not parallel to each other and are inclined with respect to the flat surface 40S parallel to the reference plane.

Note that the disclosure is not limited to the above, and the protrusion 41 may be formed to include a curved surface having a curved surface shape protruding with respect to the flat surface 40S portion, for example. In this case, the first inclined surface 41A and the second inclined surface 41B may be formed as a part of the curved surface.

On each of the first inclined surface 41A and the second inclined surface 41B, for example, the lower electrode 20, the MR elements 10, and the upper electrode 30 are stacked in order. A plurality of MR elements 10 are arranged on each of the first inclined surface 41A and the second inclined surface 41B so as to be spaced apart from each other in the X-axis direction. As shown in FIG. 16, in the MR element 10 provided on the first inclined surface 41A, the lower electrode 20, the MR element 10, and the upper electrode 30 are stacked in order in the V-axis direction, which is the normal direction of the first inclined surface 41A. In the MR element 10 provided on the first inclined surface 41A, a free layer 11, an intermediate layer 13, and a magnetization pinned layer 12 are stacked in order in the V-axis direction.

As shown in FIG. 16, in the MR element 10 provided on the second inclined surface 41B, the lower electrode 20, the MR element 10, and the upper electrode 30 are stacked in order in the W-axis direction, which is the normal direction of the second inclined surface 41B. In the MR element 10 provided on the second inclined surface 41B, the free layer 11, the intermediate layer 13, and the magnetization pinned layer 12 are stacked in order in the W-axis direction.

The magnetization of the magnetization pinned layer 12 of the MR element 10 provided on the first inclined surface 41A may include a component in a direction parallel to the U-axis direction. In this case, a direction of the sensitivity axis of the MR elements 10 provided on the first inclined surface 41A is parallel to the U-axis direction. The magnetization of the magnetization pinned layer 12 of the MR element 10 provided on the second inclined surface 41B may include a component in the direction parallel to the T-axis direction. In this case, a direction of the sensitivity axis of the MR element 10 provided on the second inclined surface 41B is parallel to the T-axis direction.

As described above, the U axis and the Taxis are inclined with respect to the Y axis. Therefore, when a magnetic field in the Y-axis direction is applied, the MR element 10 provided on the first inclined surface 41A are sensitive to a magnetic field component obtained by projecting the magnetic field in the Y-axis direction onto the U-axis direction. The MR element 10 provided on the first inclined surface 41A can detect the magnetic field component in the U-axis direction when the magnetic field in the Y-axis direction is decomposed into the magnetic field component in the V-axis direction and the magnetic field component in the U-axis direction.

Similarly, when a magnetic field in the Y-axis direction is applied, the MR element 10 provided on the second inclined surface 41B are sensitive to a magnetic field component obtained by projecting the magnetic field in the Y-axis direction onto the T-axis direction. The MR element 10 provided on the second inclined surface 41B can detect the magnetic field component in the T-axis direction when the magnetic field in the Y-axis direction is decomposed into the magnetic field component in the W-axis direction and the magnetic field component in the T-axis direction.

As described above, the MR element 10 provided on the first inclined surface 41A are sensitive to a magnetic field component obtained by projecting the magnetic field in the Y-axis direction onto the U-axis direction parallel to the first inclined surface 41A. The MR element 10 provided on the first inclined surface 41A can therefore generate a detection value corresponding to the magnetic field in the Y-axis direction. The MR element 10 provided on the second inclined surface 41B is sensitive to magnetic field component obtained by projecting the magnetic field in the Y-axis direction onto the T-axis direction parallel to the second inclined surface 41B. Therefore, the MR element 10 provided on the second inclined surface 41B can also generate a detection value corresponding to the magnetic field in the Y-axis direction.

Similarly, the MR element 10 provided on the first inclined surface 41A is sensitive to magnetic field components obtained by projecting the magnetic field in the Z-axis direction onto the U-axis direction parallel to the first inclined surface 41A. Therefore, the MR element 10 provided on the first inclined surface 41A can also generate a detection value corresponding to the magnetic field in the Z-axis direction. The MR element 10 provided on the second inclined surface 41B is sensitive to a magnetic field component obtained by projecting the magnetic field in the Z-axis direction onto the T-axis direction parallel to the second inclined surface 41B. Therefore, the MR element 10 provided on the second inclined surface 41B can also generate a detection value corresponding to the magnetic field in the Z-axis direction.

In the magnetic sensor 1A, the plurality of MR elements 10 provided on the plurality of first inclined surfaces 41A of the plurality of protrusions 41 are connected to each other. In the magnetic sensor 1A, the plurality of MR elements 10 provided on the plurality of second inclined surfaces 41B of the plurality of protrusions 41 are connected to each other.

Hereinafter, the directions of the axes in which the MR element 10 can generate a detection value corresponding to a magnetic field will be collectively referred to as a first direction. In a case of the example embodiment, for example, the U-axis direction, which is a direction parallel to the first inclined surface 41A, may be the first direction. For example, when the U-axis direction is the first direction, the magnetic field component in the X-axis direction orthogonal to the U-axis is a magnetic field component in a second direction. In the case of the example embodiment, the V-axis direction and the W-axis direction may be a third direction.

Here, the protrusion 41 on the left side in FIG. 16 is also referred to as a first protrusion 411 for convenience of description, and the protrusion 41 on the right side in FIG. 16 is also referred to as a second protrusion 412 for convenience of description. The MR element 10 provided on the first inclined surface 41A of the first protrusion 411 is also referred to as an MR element 10A, and the MR element 10 provided on the second inclined surface 41B of the first protrusion 411 is also referred to as an MR element 10B. The MR element 10 provided on the second inclined surface 41B of the second protrusion 412 is also referred to as an MR element 10C.

As shown in FIGS. 15 and 16, in the magnetic sensor 1A, an element interval LU1 between the MR element 10A provided on the first inclined surface 41A of the first protrusion 411 and the MR element 10B provided on the second inclined surface 41B of the first protrusion 411 may be defined as follows. Here, as illustrated in FIG. 16, a plane extended from the plane in which the MR element 10A extend is provisionally denoted as PL1. An end of the MR element 10A closest to the MR element 10B in the Y-axis direction is provisionally denoted as a point P11, and an end of the MR element 10B closest to the MR element 10A in the Y-axis direction is provisionally denoted as a point P12. An intersection point of a normal line passing through the point P12 and perpendicular to the plane PL1 and the plane PL1 is represented as a point P13. A distance between the point P11 and the point P13 in the direction along the plane PL1 are represented as an element interval LU1 in the U-axis direction.

An element interval LU2 may be defined as follows, the element interval LU2 being between the MR element 10A provided on the first inclined surface 41A of the first protrusion 411 and the MR element 10C provided on the second inclined surface 41B of the second protrusion 412, which is another protrusion 41 adjacent to the first protrusion 411 in the Y-axis direction and located on the opposite side of the first inclined surface 41A of the first protrusion 411 from the second inclined surface 41B of the first protrusion 411. Here, an end of the MR element 10A closest to the MR element 10C in the Y-axis direction is provisionally denoted as a point P21, and an end of the MR element 10C closest to the MR element 10A in the Y-axis direction is provisionally denoted as a point P22. An intersection point of a normal line passing through the point P22 and perpendicular to the plane PL1 and the plane PL1 is represented as a point P23. A distance between the points P21 and P23 in the direction along the plane PL1 is represented as the element interval LU2 in the U-axis direction.

Note that the MR elements 10 arranged in the Y-axis direction at the same position in the X-axis direction, such as the MR elements 10A, 10B, and 10C, may be referred to as the MR elements 10 adjacent to each other in the Y-axis direction.

The magnetic sensor 1A may be configured such that the element interval LU1 is 0.5 times or more the dimension D of each of the plurality of MR elements 10 (0.5×D≤LU1). The element interval LU2 may be configured to be 0.5 times or more the dimension D of each of the plurality of MR elements 10 (0.5×D≤LU2). Note that the element interval LU1 and the element interval LU2 may be substantially equal to each other or may be different from each other. In the magnetic sensor 1A, the element interval LU1 or the element interval LU2 corresponds to the element interval L1. By satisfying the relationship 0.5×D≤L1, the magnetic sensor 1A can suppress variation in the sensitivity when the magnetic field component MFx in the X-axis direction, which is a direction perpendicular to the sensitivity axis, is applied.

The magnetic sensor 1A can suppress variations in the sensitivities of the plurality of MR elements 10 when a magnetic field in the first direction, which is the sensitive axis direction of the plurality of MR elements 10, is applied. For example, when the first direction is the U-axis direction, the magnetic field in the U-axis direction is considered to be a projection of the magnetic field in the Y-axis direction onto the U-axis direction, and thus it can be said that the variations in the sensitivities of the plurality of MR elements 10 when the magnetic field in the Y-axis direction is applied can be suppressed. These are derived by interpreting the sensitive axis direction of the plurality of MR elements 10 included in the magnetic sensor 1A as the first direction in the simulation results illustrated in FIGS. 9A, 9B, 10A, and 10B.

Furthermore, the magnetic sensor 1A may be configured such that the element intervals LU1 and LU2 are 1.5 times or more the dimension D of each of the plurality of MR elements 10 (1.5×D≤L1). In this case, the variations described above can be further suppressed.

The element interval LU1 may be smaller than the element interval LU2 (LU1<LU2). In the direction along the plane PL1, the element interval LU1 in the U-axis direction between the MR element 10A provided on the first inclined surface 41A of the first protrusion 411 and the MR element 10B provided on the second inclined surface 41B of the first protrusion 411 may be smaller than the element interval LU2 in the U-axis direction between the MR element 10A provided on the first inclined surface 41A of the first protrusion 411 and the MR element 10B provided on the second inclined surface 41B of the second protrusion 412, which is another protrusion adjacent to the first protrusion 411.

The element intervals LX1 and LX2 in the X-axis direction between the plurality of MR elements 10 provided on the first inclined surface 41A and the second inclined surface 41B, respectively, may be the same as those in the magnetic sensor 1 according to the first example embodiment.

The other configurations and the like of the example embodiment are similar to those of the first example embodiment.

### Third Example Embodiment

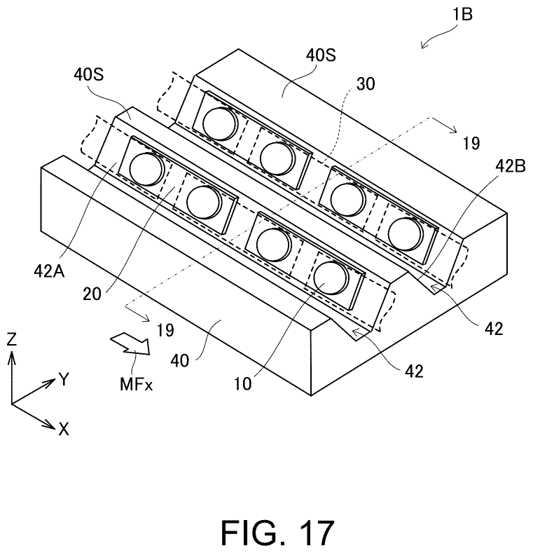

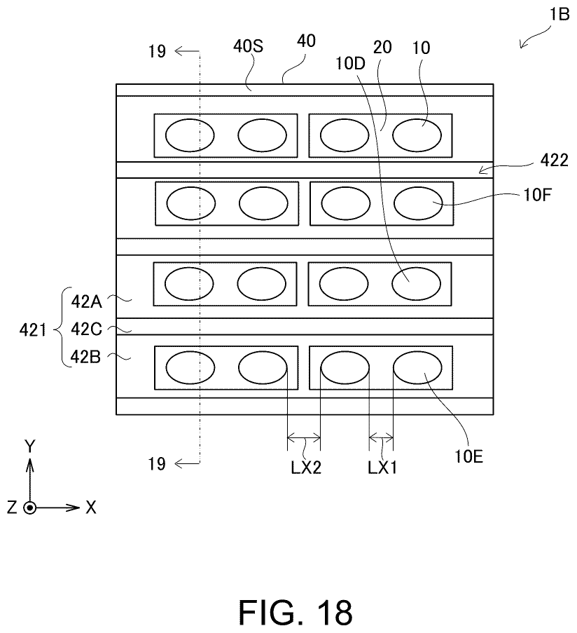

Next, with reference to FIGS. 17, 18, and 19, a configuration of a magnetic sensor 1B according to a third example embodiment of the disclosure is described. The magnetic sensor 1B corresponds to a specific example of a magnetic sensor according to one aspect of the disclosure. FIG. 17 is a perspective view schematically showing a configuration example of an appearance of the magnetic sensor 1B. FIG. 18 is a plan view showing a planar configuration example of the magnetic sensor 1B. FIG. 19 is a cross-sectional view showing a cross-sectional configuration example of the magnetic sensor 1B. Note that FIG. 19 illustrates a cross section taken along line 19-19 shown in FIGS. 17 and 18.

The magnetic sensor 1B includes a substrate 40, as in the magnetic sensor 1A according to the second example embodiment. In the magnetic sensor 1B, the substrate 40 includes a plurality of recesses 42, each of which is formed by selectively digging down a partial region of a flat surface 40S parallel to the reference plane (XY plane), instead of the plurality of protrusions 41 in the second example embodiment. The plurality of recesses 42 are arranged to be adjacent to each other in the Y-axis direction, for example.

Similarly to the magnetic sensor 1A, the magnetic sensors 1B are configured to be able to detect, for example, a magnetic field parallel to the Z-axis direction and a magnetic field parallel to the Y-axis direction. In this case, at least some of the MR elements 10 are arranged on an inclined surface that is inclined with respect to the XY plane. A direction of a sensitivity axis of the MR element 10 disposed on the inclined surface may be set to any direction parallel to the inclined surface, for example.

Each of the plurality of recesses 42 includes, for example, a first inclined surface 42A, a second inclined surface 42B, and a bottom surface 42C that extend in the X-axis direction. The first inclined surface 42A and the second inclined surface 42B are not parallel to each other and are inclined with respect to the flat surface 40S parallel to the reference plane. Note that the disclosure is not limited to the above, and the recess 42 may be formed to include a curved surface having a curved surface shape gently recessed with respect to the flat surface 40S, for example. In this case, the first inclined surface 42A and the second inclined surface 42B may be formed as a part of the curved surface.

Note that, in the description of the example embodiment, a direction perpendicular to the flat surface 40S of the substrate 40 and directed from the bottom surface 42C of the recess 42 toward the flat surface 40S is defined as a +Z direction, and a direction directed from the flat surface 40S toward the bottom surface 42C of the recess 42 is defined as a −Z direction. In addition, a T direction, a U direction, a V direction, and a W direction illustrated in FIG. 19 may be the same as those in the second example embodiment.

The first inclined surface 42A is a flat surface parallel to both the T-axis and the X-axis. The normal line of the first inclined surface 42A is parallel to the W-axis. The second inclined surface 42B is a flat surface parallel to both the U-axis and the X-axis. The normal line of the second inclined surface 42B is parallel to the V-axis.

The magnetic sensor 1B includes a plurality of MR elements 10, a plurality of lower electrodes 20, and a plurality of upper electrodes 30, as in the magnetic sensor 1A according to the second example embodiment. On each of the first inclined surface 42A and the second inclined surface 42B, for example, the lower electrode 20, the MR element 10, and the upper electrode 30 are stacked in order. A plurality of MR elements 10 are arranged on each of the first inclined surface 42A and the second inclined surface 42B so as to be spaced apart from each other in the X-axis direction. As shown in FIG. 19, in the MR element 10 provided on the first inclined surface 42A, the lower electrode 20, the MR element 10, and the upper electrode 30 are stacked in order in the W-axis direction, which is the normal direction of the first inclined surface 42A. In the MR element 10 provided on the first inclined surface 42A, a free layer 11, an intermediate layer 13, and a magnetization pinned layer 12 are stacked in order in the W-axis direction.

As shown in FIG. 19, in the MR element 10 provided on the second inclined surface 42B, the lower electrode 20, the MR element 10, and the upper electrode 30 are stacked in order in the V-axis direction, which is the normal direction of the second inclined surface 42B. Furthermore, in the MR element 10 provided on the second inclined surface 42B, the free layer 11, the intermediate layer 13, and the magnetization pinned layer 12 are stacked in order in the V-axis direction.

The magnetization pinned layers 12 of the MR element 10 provided on the first inclined surface 42A may be magnetized in a direction parallel to the T-axis direction. In this case, a first direction, which is the direction of the sensitivity axis of the MR element 10 provided on the first inclined surface 42A, is parallel to the T-axis direction. The magnetization pinned layers 12 of the MR element 10 provided on the second inclined surface 42B may be magnetized in a direction parallel to the U-axis direction. In this case, the first direction, which is the direction of the sensitivity axis of the MR element 10 provided on the second inclined surface 42B, is parallel to the U-axis direction.

As described above, the U axis and the Taxis are inclined with respect to the Y axis. Therefore, when a magnetic field in the Y-axis direction is applied, the MR element 10 provided on the first inclined surface 42A are sensitive to a magnetic field component obtained by projecting the magnetic field in the Y-axis direction onto the T-axis direction. The MR element 10 provided on the first inclined surface 42A can detect a magnetic field component in the T-axis direction when the magnetic field in the Y-axis direction is decomposed into a magnetic field component in the W-axis direction and the magnetic field component in the T-axis direction.

Similarly, when a magnetic field in the Y-axis direction is applied, the MR element 10 provided on the second inclined surface 42B are sensitive to a magnetic field component obtained by projecting the magnetic field in the Y-axis direction onto the U-axis direction. The MR element 10 provided on the second inclined surface 42B can detect a magnetic field component in the U-axis direction when the magnetic field in the Y-axis direction is decomposed into a magnetic field component in the V-axis direction and the magnetic field component in the U-axis direction.

As described above, the MR element 10 provided on the first inclined surface 42A is sensitive to the magnetic field component obtained by projecting the magnetic field in the Y-axis direction onto the T-axis direction parallel to the first inclined surface 42A. The MR element 10 provided on the first inclined surface 42A can therefore generate a detection value corresponding to the magnetic field in the Y-axis direction. The MR element 10 provided on the second inclined surface 42B is sensitive to the magnetic field component obtained by projecting the magnetic field in the Y-axis direction onto the U-axis direction parallel to the second inclined surface 42B. Therefore, the MR element 10 provided on the second inclined surface 42B can also generate a detection value corresponding to the magnetic field in the Y-axis direction.

Similarly, the MR element 10 provided on the first inclined surface 42A is sensitive to the magnetic field component obtained by projecting the magnetic field in the Z-axis direction onto the T-axis direction parallel to the first inclined surface 42A. Therefore, the MR element 10 provided on the first inclined surface 42A can also generate a detection value corresponding to the magnetic field in the Z-axis direction. The MR element 10 provided on the second inclined surface 42B is sensitive to the magnetic field component obtained by projecting the magnetic field in the Z-axis direction onto the U-axis direction parallel to the second inclined surface 42B. Therefore, the MR element 10 provided on the second inclined surface 42B can also generate a detection value corresponding to the magnetic field in the Z-axis direction. In the magnetic sensor 1B, the plurality of MR elements 10 provided on the plurality of first inclined surfaces 42A of the plurality of recesses 42 are connected to each other. In the magnetic sensor 1B, the plurality of MR elements 10 provided on the plurality of second inclined surfaces 42B of the plurality of recesses 42 are connected to each other.

The directions of the axes in which the MR element 10 can generate a detection value corresponding to a magnetic field will be hereinafter collectively referred to as a first direction. In a case of the example embodiment, for example, when the T-axis direction is the first direction, a magnetic field in the X-axis direction orthogonal to the T-axis is a magnetic field in a second direction that is a direction perpendicular to the sensitivity axis. In the case of the example embodiment, the V-axis direction and the W-axis direction may be set as a third direction.

Here, the recess 42 on the left side in FIG. 19 is also referred to as a first recess 421 for convenience of description, and the recess 42 on the right side in FIG. 19 is also referred to as a second recess 422 for convenience of description. The MR element 10 provided on the first inclined surface 42A of the first recess 421 is also referred to as an MR element 10D, and the MR element 10 provided on the second inclined surface 42B of the first recess 421 is also referred to as an MR element 10E. The MR element 10 provided on the second inclined surface 42B of the second recess 422 is also referred to as an MR element 10F.

As shown in FIG. 18 and FIG. 19, in the magnetic sensors 1B, an element interval LT1 between the MR element 10D provided on the first inclined surface 42A of the first recess 421 and the MR element 10E provided on the second inclined surface 42B of the first recess 421 may be defined as follows. Here, as illustrated in FIG. 19, a plane obtained by extending the plane in which the MR elements 10D extend is provisionally denoted as PL2. An end of the MR element 10D closest to the MR element 10E in the Y-axis direction is provisionally denoted as a point P31, and an end of the MR element 10E closest to the MR element 10D in the Y-axis direction is provisionally denoted as a point P32. An intersection point of a normal line passing through the point P32 and perpendicular to the plane PL2 and the plane PL2 is represented as a point P33. A distance between the point P31 and the point P32 in a direction along the plane PL2 are represented as the element interval LT1 in the T-axis direction.

An element interval LT2 between the MR element 10D provided on the first inclined surface 42A of the first recess 421 and the MR element 10F provided on the second inclined surface 42B of the second recess 422, which is another recess 42 adjacent to the first recess 421 in the Y-axis direction and located on the opposite side of the first inclined surface 42A of the first recess 421 from the second inclined surface 42B of the first recess 421, may be defined as follows. Here, an end of the MR element 10D closest to the MR element 10F in the Y-axis direction is provisionally denoted as a point P41, and an end of the MR element 10F closest to the MR element 10D in the Y-axis direction is provisionally denoted as a point P42. An intersection point of a normal line passing through the point P42 and perpendicular to the plane PL2 and the plane PL2 is represented as a point P43. A distance between the points P41 and P43 in a direction along the plane PL2 is represented as the element interval LT2 in the T-axis direction.

Note that the MR elements 10 arranged in the Y-axis direction at the same position in the X-axis direction, such as the MR elements 10D, 10E, and 10F, may be referred to as the MR elements 10 adjacent to each other in the Y-axis direction.

The magnetic sensor 1B may be configured such that the element interval LT1 is not less than 0.5 times the dimension D of each of the plurality of MR elements 10 (0.5×D≤LT1). The element interval LT2 may be configured to be 0.5 times or more the dimension D of each of the plurality of MR elements 10 (0.5×D≤LT2).

Note that the element interval LT1 may be defined in the same manner as the element interval LU1 described in the second example embodiment. The element interval LT2 may be defined in the same manner as the element interval LU2 described in the second example embodiment. The element interval LT1 and the element interval LT2 may be substantially equal to each other or may be different from each other. In the magnetic sensor 1B, the element interval LT1 or the element interval LT2 corresponds to the element interval L1.

By satisfying the relationship 0.5×D≤L1, the magnetic sensor 1B can suppress variation in the sensitivity when the magnetic field component MFx in the X-axis direction, which is a direction perpendicular to the sensitivity axis, is applied.

The magnetic sensor 1B can suppress variations in the sensitivities of the plurality of MR elements 10 when a magnetic field in the first direction, which is the sensitive axis direction of the plurality of MR elements 10, is applied. For example, when the first direction is the T-axis direction, the magnetic field in the T-axis direction is considered to be a projection of the magnetic field in the Y-axis direction onto the T-axis direction, and thus it can be said that the variation when the magnetic field in the Y-axis direction is applied can be suppressed. These are derived by interpreting the sensitive axis direction of the plurality of MR elements 10 included in the magnetic sensor 1B as the first direction in the simulation results illustrated in FIGS. 9A, 9B, 10A, and 10B.

Furthermore, the magnetic sensor 1B may be configured such that the element intervals LT1 and LT2 are 1.5 times or more the dimension D of each of the plurality of MR elements 10 (1.5×D≤L1). In this case, the variation described above can be further suppressed.

The element intervals LX1 and LX2 in the X-axis direction between the plurality of MR elements 10 provided on the first inclined surface 42A and the second inclined surface 42B, respectively, may be the same as those in the magnetic sensor 1 according to the first example embodiment.

The other configurations and the like of the example embodiment are similar to those of the first and second example embodiments.

### Fourth Example Embodiment

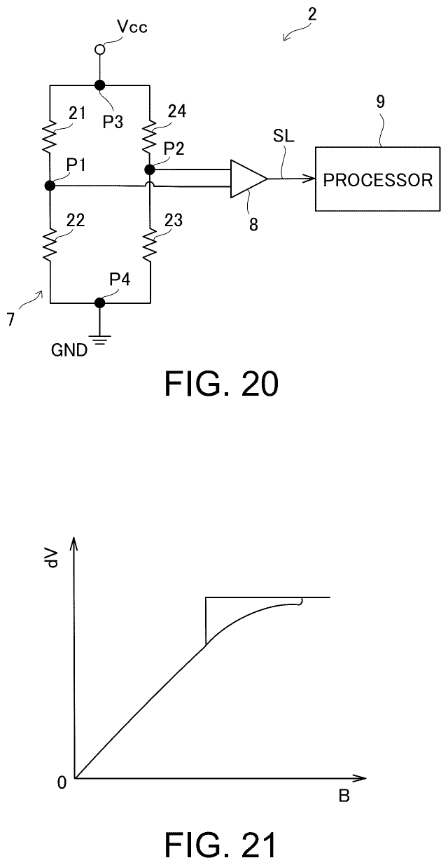

Next, a configuration of a magnetic sensor device 2 according to a fourth example embodiment of the disclosure will be described with reference to FIG. 20. FIG. 20 is a circuit diagram schematically showing a circuit configuration of the magnetic sensor device 2. As shown in FIG. 20, the magnetic sensor device 2 includes a bridge circuit 7, a difference detector 8, and a processor 9. The magnetic sensor device 2 is configured to detect a change in the strength of the magnetic field to be detected applied to the magnetic sensor device 2 by using a change in the output from the bridge circuit 7.

The bridge circuit 7 includes four resistors 21, 22, 23, and 24. The bridge circuit 7 is formed by connecting the resistor 21 and the resistor 22 connected in series and the resistor 23 and the resistor 24 connected in series, in parallel with each other. One end of the resistor 21 and one end of the resistor 22 are connected at a connection point P1. One end of the resistor 23 and one end of the resistor 24 are connected at a connection point P2. The other end of the resistor 21 and the other end of the resistor 24 are connected at a connection point P3. The other end of the resistor 22 and the other end of the resistor 23 are connected at a connection point P4. The connection point P3 is set to a first potential, and the connection point P4 is set to a second potential.

In the example shown in FIG. 20, the connection point P3 is connected to a power supply Vcc, and the connection point P4 is connected to a ground terminal GND. The connection points P1 and P2 are connected to input terminals of the difference detector 8, for example.

In the bridge circuit 7, the magnetic sensor 1 described in the first example embodiment may be adopted as each of the resistors 21 and 23. Each of the resistors 21 and 23 can detect the strength of the magnetic field in the first direction to be detected. For example, when the first direction is the X-axis direction, the magnetic sensor 1 can detect the strength of the magnetic field component MFx in the X-axis direction. In this case, the direction M12 of the magnetization of the magnetization pinned layer 12 in the magnetic sensor 1 as the resistor 21 and the direction M12 of the magnetization of the magnetization pinned layer 12 in the magnetic sensor 1 as the resistor 23 may both be set to the +X direction, for example. Each of the resistors 22 and 24 in the bridge circuit 7 is, for example, a fixed resistor.

Note that each of the resistors 22 and 24 is not limited to a fixed resistor. The magnetic sensor 1 can be adopted as each of the resistors 22 and 24. In this case, a direction M12 of the magnetization of the magnetization pinned layer 12 in the magnetic sensor 1 as the resistor 21 and a direction M12 of the magnetization of the magnetization pinned layer 12 in the magnetic sensor 1 as the resistor 23 may be both set to the +X direction. A direction M12 of the magnetization of the magnetization pinned layer 12 in the magnetic sensor 1 as the resistor 22 and a direction M12 of the magnetization of the magnetization pinned layer 12 in the magnetic sensor 1 as the resistor 24 may be both set to the −X direction, for example. The disclosure is not limited to the above, and the direction of magnetization in the resistors 21 and 23 and the direction of magnetization in the resistors 22 and 24 may be set to be opposite to each other.

When the magnetic sensor 1 includes two or more resistors among the resistors 21 to 24, the magnetic sensor 1 including the two or more resistors may be integrated or may be separate.

In the magnetic sensor device 2, signals taken out from the connection points P1 and P2 of the bridge circuit 7 flow into the difference detector 8. The difference detector 8 detects a voltage difference between the connection points P3 and P4 when a voltage is applied between the connection point P3 and P4, which is a differential output dV being a differential between a voltage drop occurring in the resistor 21 and a voltage drop occurring in the resistor 24, and outputs the differential output dV as a differential signal SL to the processor 9.

In the magnetic sensor device 2, when a resistance value of the resistor 22 and a resistance value of the resistor 24 are configured to match a resistance value of the resistor 21 and a resistance value of the resistor 23 in the zero magnetic field, the differential output dV is 0 in the initial state in which the magnetic field component MFx is not applied. In a state in which the magnetic field component MFx is applied to the bridge circuit 7, each of the magnetic sensor 1 as the resistor 21 and the magnetic sensor 1 as the resistor 23 exhibits a change in resistance value corresponding to the strength of the applied magnetic field component MFx. Therefore, the differential output dV corresponding to the strength of the magnetic field component MFx is generated.

FIG. 21 is a characteristic chart schematically showing the relationship between the magnetic flux density B (horizontal axis) representing the strength of the magnetic field component MFx and the differential output dV (vertical axis) in the magnetic sensor device 2. As shown in FIG. 21, in the magnetic sensor device 2, the magnetic flux density B and the differential output dV have a proportional relationship in a range of the magnetic flux density B of a certain magnitude or less. The processor 9 calculates the strength of the magnetic field component MFx applied to the bridge circuit 7, based on the difference signal SL from the difference detector 8 according to the correlation shown in FIG. 21.

As described above, the magnetic sensor device 2 can determine the strength of the applied magnetic field component MFx.

Note that the magnetic sensor device 2 may include a first bridge circuit and a second bridge circuit instead of the bridge circuit 7 or in addition to the bridge circuit 7. The configuration of each of the first bridge circuit and the second bridge circuit is similar to the configuration of the bridge circuit 7.

Each resistor of the first bridge circuit may be constituted by the plurality of MR elements 10 arranged on the plurality of first inclined surfaces 41A of the plurality of protrusions 41 of the magnetic sensor 1A according to the second example embodiment. Each resistor of the second bridge circuit may be constituted by the plurality of MR elements 10 arranged on the plurality of second inclined surfaces 41B of the plurality of protrusions 41 of the magnetic sensor 1A. In this case, the strength of the magnetic field component in the Y-axis direction applied to the first and second bridge circuits and the strength of the magnetic field component in the Z-axis direction applied to the first and second bridge circuits can be calculated based on the differential signal generated from the first bridge circuit and the differential signal generated from the second bridge circuit.

Alternatively, each resistor of the first bridge circuit may be constituted by the plurality of MR elements 10 arranged on the plurality of first inclined surfaces 42A of the plurality of recesses 42 of the magnetic sensor 1B according to the third example embodiment. Each resistor of the second bridge circuit may be constituted by the plurality of MR elements 10 arranged on the plurality of second inclined surfaces 42B of the plurality of recesses 42 of the magnetic sensor 1B. In this case, the strength of the magnetic field component in the Y-axis direction applied to the first and second bridge circuits and the strength of the magnetic field component in the Z-axis direction applied to the first and second bridge circuits can be calculated based on the differential signal generated from the first bridge circuit and the differential signal generated from the second bridge circuit.

The other configurations and the like of the example embodiment are similar to those of the first, second, and third example embodiments.

### Fifth Example Embodiment

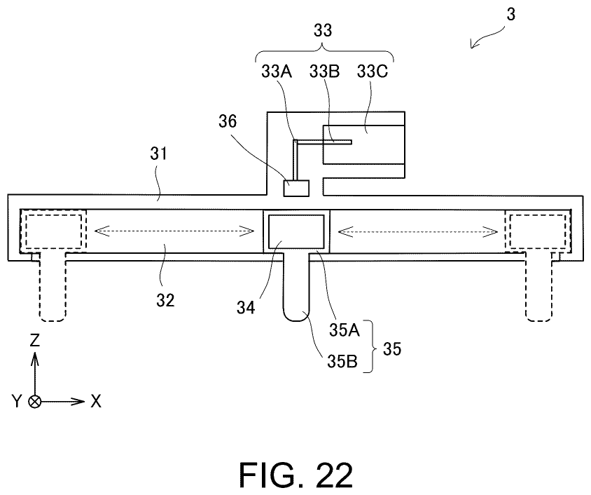

Next, a configuration of a magnetic sensor device 3 according to a fifth example embodiment of the disclosure will be described with reference to FIG. 22. FIG. 22 is a schematic diagram illustrating an overall configuration example of the magnetic sensor device 3. Note that the magnetic sensor device 3 illustrated in FIG. 22 is an example. In an example embodiment, the respective components constituting the magnetic sensor device 3, and the dimensions, shapes, and arrangement positions thereof are not limited to those illustrated in FIG. 22. As illustrated in FIG. 22, the magnetic sensor device 3 includes a sensor unit 36 including the magnetic sensor 1 described in the first example embodiment, and a housing 31 that houses the sensor unit 36.

The housing 31 includes, for example, a cavity portion 32 and a connector portion 33. A magnetic field generating unit 34 is held in the cavity portion 32 so as to be movable in the X-axis direction. The magnetic sensor device 3 is a so-called linear sensor, and detects a position of the magnetic field generating unit 34 with respect to the sensor unit 36.

The connector portion 33 includes a wire 33A connected to the sensor unit 36, a terminal 33B provided at a tip of the wire 33A, and a connecting portion 33C where the terminal 33B is exposed. A connector of an external device is connected to the connector portion 33 in order to transmit and receive signals to and from the external device.

The cavity portion 32 is a portion that accommodates the magnetic field generating unit 34 so as to be reversibly movable along the X-axis direction, and extends in the X-axis direction.

The magnetic field generating unit 34 is, for example, a permanent magnet, and is held by a holding member 35. The magnetic field generating unit 34 is reversibly movable along the X-axis direction integrally with the holding member 35.

The holding member 35 has a holding portion 35A for holding the magnetic field generating unit 34, and a connecting portion 35B connected to a target object whose position in the X-axis direction is to be detected by the magnetic sensor 1 of the sensor unit 36.

According to the magnetic sensor device 3, the housing 31 is fixed to a reference object that is an object different from the target object of the position detection, and thus it is possible to detect the position and a movement amount of the target object of the position detection with respect to the reference object.

The other configurations and the like of the example embodiment are similar to those of the first example embodiment.

### Sixth Example Embodiment

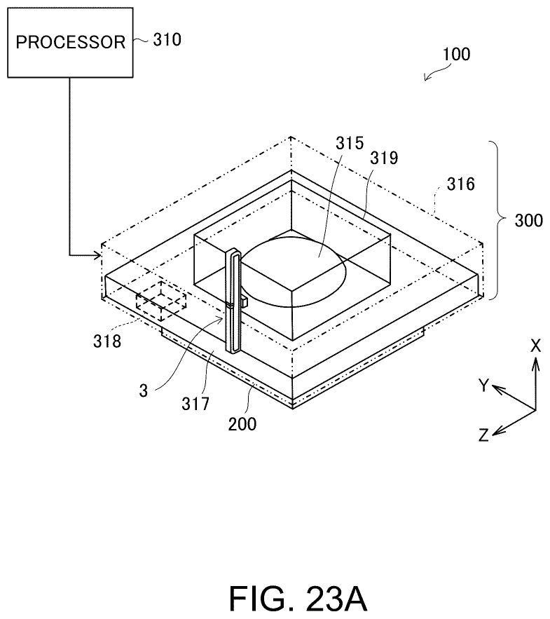

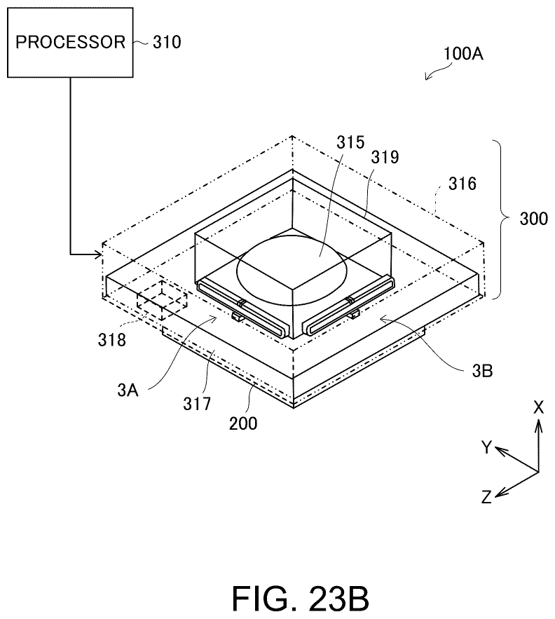

Next, a configuration of an imaging device 100 according to a fourth example embodiment of the disclosure will be described with reference to FIG. 23A. FIG. 23A is a perspective view showing an example of an overall configuration of the imaging device 100. Note that the imaging device 100 shown in FIG. 23A of the drawing is an example. In an example embodiment, the respective components constituting the imaging device 100, and the dimensions, shapes, and arrangement positions thereof are not limited to those shown in FIG. 23A.

The imaging device 100 constitutes, for example, a part of a camera for a smartphone including an autofocus mechanism. The imaging device 100 includes an image sensor 200 that acquires an image using, for example, a CMOS or the like, and a lens module 300 that guides light from a subject to the image sensor 200.

The lens module 300 includes the magnetic sensor device 3 described in the fifth example embodiment, a lens 315, a housing 316, a base body 317, a drive unit 318, and a holding member 319. The magnetic sensor device 3 is a magnetic position detection device, and is a mechanism that detects a position of the lens 315 when automatic focusing is performed for incident light so that the incident light incident from a subject is imaged on an imaging surface of the image sensor 200.

The drive unit 318 is an actuator that generates a driving force for moving the lens 315 to perform focusing for incident light, for example. The housing 316 accommodates the magnetic sensor device 3 and the like and protects them.

Note that, in the imaging device 100 in FIG. 23A, the magnetic sensor device 3 is provided in a posture in which the magnetic field generating unit 34 is reversibly moved along the X-axis direction. In the imaging device 100 in FIG. 23A, the drive unit 318 moves the magnetic field generating unit 34 and the lens 315 in the X-axis direction and detects the positions of the magnetic field generating unit 34 and the lens 315 in the X-axis direction, based on the control by the processor 310.

The lens 315 is arranged above the base body 317 in a posture in which the optical axis direction of the lens matches the X axis. The base body 317 has an opening for passing light that has passed through the lens 315. The lens module 300 and the image sensor 200 are aligned with each other so that light from a subject that has passed through the lens 315 and the opening of the base body 317 in order is incident on the image sensor 200.

The holding member 319 is a member that integrally holds the magnetic field generating unit 34 of the magnetic sensor device 3 and the lens 315. The holding member 319 has, for example, a cylindrical shape configured so that the lens 315 can be mounted therein. The holding member 319 is provided so as to be reversibly movable along the optical axis direction (X-axis direction) of the lens 315 with respect to the base body 317. The base body 317 supports the holding member 319 via a plurality of biasing members such as springs so that the holding member 319 can move in the X-axis direction with respect to the base body 317.

The operation of the imaging device 100 is controlled by a processor 310 provided outside the imaging device 100. The processor 310 includes a circuit including, for example, a central processing unit (CPU) that is an arithmetic processing unit, a read only memory (ROM) that is a storage element storing a program, an arithmetic parameter, and the like used by the CPU, a random access memory (RAM) that is a storage element temporarily storing a parameter and the like that appropriately changes in execution of the CPU, and the like. Note that the processor 310 may be configured by a circuit element such as an ASIC in which a program, an operation parameter, and the like capable of controlling the imaging device 100 are incorporated.

The autofocus mechanism is configured to detect a state in which focus is achieved on the subject, by using, for example, the image sensor 200 or an autofocus sensor. The processor 310 changes the relative position of the lens 315 with respect to the base body 317 along the X axis by the driving force of the drive unit 318 so that the subject is in focus. To be more specific, this enables automatic focusing on the subject.

Since the imaging device 100 includes the magnetic sensor device 3 of the fifth example embodiment, the position and the displacement amount of the magnetic field generating unit 34 that moves integrally with the lens 315 can be detected while reducing the overall dimension of the imaging device 100. Therefore, the imaging device 100 can perform excellent focusing while achieving compactness.

The other configurations and the like of the example embodiment are similar to those of the fifth example embodiment.

### Seventh Example Embodiment

Next, a configuration of an imaging device 100A according to a seventh example embodiment of the disclosure will be described with reference to FIG. 23B. FIG. 23B is a schematic perspective view showing an overall configuration example of the imaging device 100A according to the seventh example embodiment. In the disclosure, the imaging device may include an optical image stabilization mechanism as in the imaging device 100A.

The imaging device 100A includes two magnetic sensors 3A and 3B. The magnetic sensor devices 3A and 3B have substantially the same configuration as the magnetic sensing device 3 described in the fifth example embodiment. However, the magnetic field generating unit 34 of the magnetic sensor device 3A is provided so as to move in the Y-axis direction integrally with the lens 315, and the magnetic sensor device 3A detects the positions of the magnetic field generating unit 34 and the lens 315 in the Y-axis direction. The magnetic field generating unit 34 of the magnetic sensor device 3B is provided so as to move in the Z-axis direction integrally with the lens 315, and the magnetic sensor device 3B detects the positions of the magnetic field generating unit 34 and the lens 315 in the Z-axis direction.

The configuration of the imaging device 100A shown in FIG. 23B is substantially the same as the configuration of the imaging device 100 shown in FIG. 23A except that an optical image stabilization mechanism is provided in addition to the autofocus mechanism or instead of the autofocus mechanism.

The optical image stabilization mechanism is configured to detect hand-induced camera shake using, for example, a gyrosensor. Note that the sensor such as the gyro sensor may be provided outside the imaging device 100A. Upon detection of hand-induced camera shake by the optical image stabilization mechanism, the processor 310 controls the drive unit 318 so as to vary the position of the lens 315 relative to the base body 317 depending on the mode of the camera shake.

In the drive unit 318, the lens 315 moves in the Y-axis direction or the Z-axis direction orthogonal to the direction of the optical axis of the lens 315, for example, according to a command from the processor 310. At this time, the magnetic field generating unit 34 of the magnetic sensor device 3A and the magnetic field generating unit 34 of the magnetic sensor device 3B move together with the lens 315, and thus the position of the lens 315 is detected by the sensor unit 36 of the magnetic sensor device 3A and the sensor unit 36 of the magnetic sensor device 3B. This stabilizes the absolute position of the lens 315 to reduce the effect of the camera shake.

Note that the position of the lens 315 relative to the base body 317 is varied in a direction parallel to the Y axis or in a direction parallel to the Z axis, depending on the mode of the camera shake.

Since the imaging device 100A includes the magnetic sensor devices 3A and 3B having substantially the same configuration as the magnetic sensor 3 of the fifth example embodiment, the position (displacement amount) of the magnetic field generating unit 34 that moves integrally with the lens 315 can be detected while reducing the overall dimension of the imaging device 100A. Therefore, the imaging device 100A can perform favorable optical image stabilization while achieving compactness.

Note that the imaging device 100A may include an autofocus mechanism of the imaging device 100. In this case, the imaging device 100A can perform optical image stabilization with high accuracy and focusing with high accuracy.

The other configurations and the like of the example embodiment are similar to those of the fifth or sixth example embodiment.

As described above, a magnetic sensor according to a first aspect of the disclosure includes a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The plurality of magnetoresistive elements include a first element, a second element, and a third element. Magnetization of the magnetization pinned layer of each of the first element, the second element, and the third element includes a component in a first direction. The second element is arranged at a first interval from the first element in the first direction. The third element is arranged at a second interval from the first element in a second direction different from the first direction. Each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape. The first interval is at least 0.5 times D and at most 3 times D, where D is the maximum dimension of at least one of the first element, the second element, and the third element.

In the magnetic sensor according to the first aspect of the disclosure, at least one of the first element, the second element, and the third element may have a maximum dimension different from a maximum dimension of at least one other of the first element, the second element, and the third element. The first interval may be at least 0.5 times a largest one of the maximum dimensions of the first element, the second element, and the third element.

In the magnetic sensor according to the first aspect of the disclosure, the first element, the second element, and the third element may have the same maximum dimension.

In the magnetic sensor according to the first aspect of the disclosure, the first interval may be less than 2.8 times D, less than 1.9 times D, or at least 1.5 times D.

In the magnetic sensor according to the first aspect of the disclosure, the second interval may be at least 0.5 times D. Alternatively, the second interval may be greater than 0 and at most 3 times D, and may be at least 0.5 times D.

In the magnetic sensor according to the first aspect of the disclosure, the second interval may be greater than the first interval. The first element, the second element, and the third element are arranged within a rectangular region having two sides extending in the first direction and two sides extending in the second direction. A dimension of the rectangular region in the second direction is greater than a dimension of the rectangular region in the first direction.

In the magnetic sensor according to the first aspect of the disclosure, the planar shape may be circular.

In the magnetic sensor according to the first aspect of the disclosure, the intermediate layer may be a tunnel barrier layer.

The magnetic sensor of the first aspect of the disclosure may further include a first electrode and a second electrode spaced from each other in the first direction. The plurality of magnetoresistive elements may further include a fourth element and a fifth element spaced from each other in the first direction. The first electrode connects the first element and the second element. The second electrode connects the fourth element and the fifth element. The first interval and an interval between the fourth element and the fifth element are greater than a distance between the first electrode and the second electrode.

A magnetic sensor according to a second aspect of the disclosure includes a first magnetoresistive element, and a second magnetoresistive element arranged at a first interval from the first magnetoresistive element in a first direction. Each of the first magnetoresistive element and the second magnetoresistive element includes a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The magnetization of the magnetization pinned layer includes a component in the first direction. Each of the first magnetoresistive element and the second magnetoresistive element has a planar shape in a plan view from a stacking direction of the magnetization pinned layer, the intermediate layer, and the free layer, the planar shape having a maximum dimension being a greatest distance between any two points on an outer edge of the planar shape. The first interval is at least 0.5 times D and at most 3 times D, where D is the maximum dimension of at least one of the first magnetoresistive element and the second magnetoresistive element.

In the magnetic sensor according to the second aspect of the disclosure, the first interval may be less than 2.8 times D. The first interval may be less than 1.9 times D.

A magnetic sensor according to a third aspect of the disclosure includes a substrate including a first inclined surface and a second inclined surface each extending in a first direction and facing in different directions, and a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer. The plurality of magnetoresistive elements include a first element arranged on the first inclined surface, a second element arranged on the first inclined surface and spaced from the first element in the first direction, a third element arranged on the second inclined surface and spaced from the first element in a second direction different from the first direction. The magnetization pinned layer, the intermediate layer, and the free layer of each of the first element and the second element are stacked in a direction intersecting with the first inclined surface. The magnetization pinned layer, the intermediate layer, and the free layer of the third element are stacked in a direction intersecting with the second inclined surface. Each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape. An interval between the first element and the third element in a third direction is at least 0.5 times D and at most 3 times D, where D is the maximum dimension of at least one of the first element, the second element, and the third element. The third direction is orthogonal to the first direction, intersects with the second direction at an angle other than 90 degrees, and is parallel to the first inclined surface.

In the magnetic sensor of the third aspect of the disclosure, the substrate may further include a third inclined surface extending in the first direction and facing a direction different from the first inclined surface. The first inclined surface is located between the second inclined surface and the third inclined surface. The plurality of magnetoresistive elements may further include a fourth element arranged on the third inclined surface and spaced from the first element in the second direction. The magnetization pinned layer, the intermediate layer, and the free layer of the fourth element may be stacked in a direction intersecting with the third inclined surface. An interval between the first element and the third element in the third direction may be smaller than an interval between the first element and the fourth element in the third direction. The substrate may include a flat surface and a protrusion protruding from the flat surface. The protrusion may include the first inclined surface and the second inclined surface. Each of the first inclined surface and the second inclined surface may be inclined with respect to the flat surface. Alternatively, the substrate may include a flat surface and a recess recessed from the flat surface. The recess may include the first inclined surface and the second inclined surface. Each of the first inclined surface and the second inclined surface may be inclined with respect to the flat surface.

A magnetic sensor according to a fourth aspect of the disclosure includes a plurality of magnetoresistive elements including at least a first magnetoresistive element and a second magnetoresistive element that are arranged adjacent to each other in a first direction, and a third magnetoresistive element that is arranged adjacent to the first magnetoresistive element in a second direction different from the first direction. Each of the plurality of magnetoresistive elements includes a magnetization free layer, a non-magnetic layer, and a magnetization pinned layer that are stacked in order in a third direction different from both the first direction and the second direction. The magnetization pinned layer is magnetized in the first direction. The magnetization free layer has a magnetic vortex structure that develops a magnetic vortex. When L1 denotes a first element interval between the first and second magnetoresistive elements in the first direction, L2 denotes a second element interval between the first and third magnetoresistive elements in the second direction, and D denotes a diameter of at least one of the first to third magnetoresistive elements, the following conditional expression is satisfied.

$$0.5 \times D \leq L 2 \qquad [ Relationship 1 ]$$

In the magnetic sensor according to the fourth aspect of the disclosure, a diameter of the first magnetoresistive element may be different from at least one of a diameter of the second magnetoresistive element and a diameter of the third magnetoresistive element. When Dmax denotes the maximum diameter among the diameter of the first magnetoresistive element, the diameter of the second magnetoresistive element, and the diameter of the third magnetoresistive element, the following conditional expression may be satisfied.

$$0 \text{.5} \times D max \leq L 2 \qquad [ Relationship 2 ]$$

In the magnetic sensor according to the fourth aspect of the disclosure, the plurality of magnetoresistive elements may have the same diameter.

In the magnetic sensor according to the fourth aspect of the disclosure, at least one of the following conditional expressions may be further satisfied.

$$1.5 \times D \leq L 2 \qquad [ Relationship 3 ]$$

$$0 < L 1 \leq 3. \times D \qquad [ Relationship 4 ]$$

$$0 < L 1 < 2.8 \times D \qquad [ Relationship 5 ]$$

$$0 < L 1 < 1.9 \times D \qquad [ Relationship 6 ]$$

$$0 < L 1 \leq 0.5 \times D \qquad [ Relationship 7 ]$$

$$0.5 \times D \leq L 1 \qquad [ Relationship 8 ]$$

$$1.5 \times D \leq L 1 \qquad [ Relationship 9 ]$$

$$0.5 \times D \leq L 1 \qquad [ Relationship 10 ]$$

$$1.5 \times D \leq L 1 \qquad [ Relationship 11 ]$$

$$0.5 \times D \leq L 1 \qquad [ Relationship 12 ]$$

$$1.5 \times D \leq L 1 \qquad [ Relationship 13 ]$$

$$L 2 \leq 3. \times D \qquad [ Relationship 14 ]$$

In the magnetic sensor according to the fourth aspect of the disclosure, an outer edge shape of each of the plurality of magnetoresistive elements may be circular.

In the magnetic sensor according to the fourth aspect of the disclosure, the plurality of magnetoresistive elements may be tunnel magnetoresistive elements.

The magnetic sensor according to the fourth aspect of the disclosure may further include a first lead and a second lead adjacent to each other in the first direction. The plurality of magnetoresistive elements may further include a fourth magnetoresistive element and a fifth magnetoresistive element. The first magnetoresistive element and the second magnetoresistive element adjacent to each other in the first direction may be provided on the first lead. The fourth and fifth magnetoresistive elements adjacent to each other in the first direction may be provided on the second lead. An interval between the first magnetoresistive element and the second magnetoresistive element in the first direction and an interval between the fourth magnetoresistive element and the fifth magnetoresistive element in the first direction may be larger than an interval between the first lead and the second lead in the first direction.

A magnetic sensor device according to one example embodiment of the disclosure includes the magnetic sensor according to one example embodiment of the disclosure as a first magnetic sensor, and the magnetic sensor according to one example embodiment of the disclosure as a second magnetic sensor. An interval between the magnetoresistive element in the first magnetic sensor and the magnetoresistive element in the second magnetic sensor in the second direction is larger than the second element interval.

The magnetic sensor device according to one example embodiment of the disclosure further includes a bridge circuit including the first magnetic sensor and the second magnetic sensor.

A lens module according to one example embodiment of the disclosure includes a magnetic sensor device including the magnetic sensor according to one example embodiment of the disclosure and a magnetic field generator configured to generate a magnetic field, and a lens having an optical axis. The magnetic sensor detects the strength of a magnetic field component of the magnetic field, the magnetic field component varying according to the position of the lens.

An imaging apparatus according to one example embodiment of the disclosure includes a lens module according to one example embodiment of the disclosure, an imaging element, a first drive unit configured to generate a first driving force to move a lens along a direction of the optical axis, and a control unit configured to control an operation of the drive unit. The control unit causes the first drive unit to generate the first driving force to move the lens along the direction of the optical axis, to thereby perform focusing on the subject.

The imaging device according to one example embodiment of the disclosure may further include a second drive unit configured to generate a second driving force to move the lens in a direction intersecting with the optical axis of the lens. The control unit may perform camera shake correction by causing the second drive unit to generate the second driving force to move the lens along the direction intersecting with the optical axis.

A magnetic sensor according to a fifth aspect of the disclosure includes at least a first magnetoresistive element and a second magnetoresistive element that are disposed adjacent to each other in a first direction. Each of the first magnetoresistive element and the second magnetoresistive element includes a magnetization free layer, a non-magnetic layer, and a magnetization pinned layer stacked in a direction different from the first direction. The magnetization pinned layer is magnetized in the first direction. The magnetization free layer has a magnetic vortex structure that develops a magnetic vortex. An interval between the first magnetoresistive element and the second magnetoresistive element in the first direction is 0.5 times or more a diameter of at least one of the first magnetoresistive element and the second magnetoresistive element.

In the magnetic sensor according to the fifth aspect of the disclosure, an interval between the first magnetoresistive element and the second magnetoresistive element in the first direction may be 3.0 times or less a diameter of at least one of the first magnetoresistive element and the second magnetoresistive element.

In the magnetic sensor according to the fifth aspect of the disclosure, an interval between the first magnetoresistive element and the second magnetoresistive element in the first direction may be less than 2.8 times a diameter of at least one of the first magnetoresistive element and the second magnetoresistive element.

In the magnetic sensor according to the fifth aspect of the disclosure, an interval between the first magnetoresistive element and the second magnetoresistive element in the first direction may be less than 1.9 times a diameter of at least one of the first magnetoresistive element and the second magnetoresistive element.

A magnetic sensor according to a sixth aspect of the disclosure includes:
a substrate including a flat surface parallel to a reference plane, a first inclined surface inclined with respect to the flat surface, and a second inclined surface adjacent to the first inclined surface in a first direction and inclined with respect to the flat surface; and
a plurality of magnetoresistive elements including at least a first magnetoresistive element and a second magnetoresistive element each arranged on the first inclined surface, and a third magnetoresistive element arranged on the second inclined surface.

The first magnetoresistive element and the second magnetoresistive element are adjacent to each other in a second direction orthogonal to the first direction and parallel to the reference plane. The first magnetoresistive element and the third magnetoresistive element are adjacent to each other in the first direction. Each of the plurality of magnetoresistive elements includes a magnetization free layer having a magnetic vortex structure, a non-magnetic layer, and a magnetization pinned layer. The magnetization pinned layer of each of the first magnetoresistive element and the second magnetoresistive element is magnetized in a third direction, the third direction being orthogonal to the first direction and parallel to the first inclined surface. The magnetization free layer, the non-magnetic layer, and the magnetization pinned layer of each of the first magnetoresistive element and the second magnetoresistive element are stacked in a direction perpendicular or substantially perpendicular to the first inclined surface. The magnetization pinned layer in the third magnetoresistive element is magnetized in a fourth direction orthogonal to the first direction and parallel to the second inclined surface. The magnetization free layer, the non-magnetic layer, and the magnetization pinned layer in the third magnetoresistive element are stacked in a direction perpendicular or substantially perpendicular to the second inclined surface.

When L1 denotes an element interval between the first and third magnetoresistive elements in the third direction, and D denotes a diameter of at least one of the first to third magnetoresistive elements, the following conditional expression is satisfied.

$$0.5 \times D \leq L 1 \qquad [ Relationship 17 ]$$

The magnetic sensor of the sixth aspect of the disclosure may further include a third inclined surface inclined with respect to the flat surface and adjacent to the first inclined surface on a side opposite to the second inclined surface in the first direction, and a fourth magnetoresistive element arranged on the third inclined surface and adjacent to the first magnetoresistive element in the first direction. The magnetization pinned layer in the fourth magnetoresistive element may be magnetized in a fifth direction orthogonal to the first direction and parallel to the third inclined surface. The magnetization free layer, the non-magnetic layer, and the magnetization pinned layer in the fourth magnetoresistive element may be stacked in a direction perpendicular or substantially perpendicular to the third inclined surface. An element interval between the first magnetoresistive element and the second magnetoresistive element in the third direction may be smaller than an element interval between the first magnetoresistive element and the fourth magnetoresistive element in the third direction.

The magnetic sensor according to the sixth aspect of the disclosure may include a protrusion that protrudes from the flat surface in the thickness direction of the substrate. The protrusion may include the first inclined surface and the second inclined surface.

The magnetic sensor according to the sixth aspect of the disclosure may include a recess that is recessed with respect to the flat surface in the thickness direction of the substrate. The recess may include the first inclined surface and the second inclined surface.

According to the magnetic sensor of the disclosure, a change in magnetic field can be detected with appropriate sensitivity.

The embodiments and modifications described above are presented for purposes of illustration and to facilitate understanding of the present disclosure, and are not intended to be limiting. Accordingly, the elements disclosed in the foregoing embodiments are intended to include all design changes and equivalents that fall within the technical scope of the present disclosure. Thus, the present disclosure is not limited to the embodiments described above, and various modifications may be made.

The technology according to the present disclosure can also be expressed, for example, as configurations shown in the following clauses. The technology according to the present disclosure is not limited to these configurations.

Clause 1. A magnetic sensor including:
a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer, in which the plurality of magnetoresistive elements include a first element, a second element, and a third element, magnetization of the magnetization pinned layer of each of the first element, the second element, and the third element includes a component in a first direction, the second element is arranged at a first interval from the first element in the first direction, the third element is arranged at a second interval from the first element in a second direction different from the first direction, each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape, and the first interval is at least 0.5 times D and at most 3 times D, where D is the maximum dimension of at least one of the first element, the second element, and the third element.

Clause 2. The magnetic sensor according to clause 1, in which
at least one of the first element, the second element, and the third element has a maximum dimension different from a maximum dimension of at least one other of the first element, the second element, and the third element, and the first interval is at least 0.5 times a largest one of the maximum dimensions of the first element, the second element, and the third element.

Clause 3. The magnetic sensor according to clause 1 or 2, in which
the first element, the second element, and the third element have the same maximum dimension.

Clause 4. The magnetic sensor according to any of clauses 1 to 3, in which
the first interval is less than 2.8 times D.

Clause 5. The magnetic sensor according to any of clauses 1 to 4, in which
the first interval is less than 1.9 times D.

Clause 6. The magnetic sensor according to clause 4, in which
the first interval is at least 1.5 times D.

Clause 7. The magnetic sensor according to clause 5, in which
the first interval is at least 1.5 times D.

Clause 8. The magnetic sensor according to any of clauses 1 to 7, in which
the second interval is at least 0.5 times D.

Clause 9. The magnetic sensor according to any of clauses 1 to 7, in which the second interval is greater than 0 and at most 3 times D.
Clause 10. The magnetic sensor according to clause 9, in which
the second interval is at least 0.5 times D.

Clause 11. The magnetic sensor according to any of clauses 1 to 10, in which the second interval is greater than the first interval.
Clause 12. The magnetic sensor according to any of clauses 1 to 11, in which
the first element, the second element, and the third element are arranged within a rectangular region having two sides extending in the first direction and two sides extending in the second direction, and
a dimension of the rectangular region in the second direction is greater than a dimension of the rectangular region in the first direction.

Clause 13. The magnetic sensor according to any of clauses 1 to 12, in which
the planar shape is circular.

Clause 14. The magnetic sensor according to any of clauses 1 to 13, further including
a first electrode and a second electrode spaced from each other in the first direction, in which
the plurality of magnetoresistive elements further include a fourth element and a fifth element spaced from each other in the first direction,
the first electrode connects the first element and the second element,
the second electrode connects the fourth element and the fifth element, and
the first interval and a distance between the fourth element and the fifth element are greater than a distance between the first electrode and the second electrode.

Clause 15. A magnetic sensor including:
a first magnetoresistive element; and
a second magnetoresistive element arranged at a first interval from the first magnetoresistive element in a first direction, in which
each of the first magnetoresistive element and the second magnetoresistive element includes
a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer,
the magnetization of the magnetization pinned layer includes a component in the first direction,
each of the first magnetoresistive element and the second magnetoresistive element has a planar shape in a plan view from a stacking direction of the magnetization pinned layer, the intermediate layer, and the free layer, the planar shape having a maximum dimension being a greatest distance between any two points on an outer edge of the planar shape, and
the first interval is at least 0.5 times D and at most 3 times D, where D is the maximum dimension of at least one of the first magnetoresistive element and the second magnetoresistive element.

Clause 16. A magnetic sensor including:
a substrate including a first inclined surface and a second inclined surface each extending in a first direction and facing in different directions; and a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer, in which the plurality of magnetoresistive elements include a first element arranged on the first inclined surface, a second element arranged on the first inclined surface and spaced from the first element in the first direction, a third element arranged on the second inclined surface and spaced from the first element in a second direction different from the first direction, the magnetization pinned layer, the intermediate layer, and the free layer of each of the first element and the second element are stacked in a direction intersecting with the first inclined surface, the magnetization pinned layer, the intermediate layer, and the free layer of the third element are stacked in a direction intersecting with the second inclined surface, each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape, and an interval between the first element and the third element in a third direction is at least 0.5 times D and at most 3 times D, where D is the maximum dimension of at least one of the first element, the second element, and the third element, the third direction being orthogonal to the first direction, intersecting with the second direction at an angle other than 90 degrees, and being parallel to the first inclined surface.

Clause 17. The magnetic sensor according to clause 16, in which
the substrate further includes a third inclined surface extending in the first direction and facing a direction different from the first inclined surface,
the first inclined surface is located between the second inclined surface and the third inclined surface,
the plurality of magnetoresistive elements further include a fourth element arranged on the third inclined surface and spaced from the first element in the second direction,
the magnetization pinned layer, the intermediate layer, and the free layer of the fourth element are stacked in a direction intersecting with the third inclined surface, and
an interval between the first element and the third element in the third direction is smaller than an interval between the first element and the fourth element in the third direction.

Clause 18. The magnetic sensor according to clause 16 or 17, in which
the substrate includes a flat surface and a protrusion protruding from the flat surface, the protrusion includes the first inclined surface and the second inclined surface, and each of the first inclined surface and the second inclined surface is inclined with respect to the flat surface.

Clause 19. The magnetic sensor according to clause 16 or 17, in which
the substrate includes a flat surface and a recess recessed from the flat surface, the recess includes the first inclined surface and the second inclined surface, and each of the first inclined surface and the second inclined surface is inclined with respect to the flat surface.

It is apparent that the disclosure can be carried out in various forms and modifications in the light of the foregoing descriptions. Accordingly, within the scope of the following clauses and equivalents thereof, the disclosure can be carried out in forms other than the foregoing example embodiments.

1. A magnetic sensor comprising:
a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer, wherein
the plurality of magnetoresistive elements include a first element, a second element, and a third element,
magnetization of the magnetization pinned layer of each of the first element, the second element, and the third element includes a component in a first direction,
the second element is arranged at a first interval from the first element in the first direction,
the third element is arranged at a second interval from the first element in a second direction different from the first direction,
each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape, and
the first interval is at least 0.5 times D and at most 3 times D, where D is the maximum dimension of at least one of the first element, the second element, and the third element.

2. The magnetic sensor according to claim 1, wherein
at least one of the first element, the second element, and the third element has a maximum dimension different from a maximum dimension of at least one other of the first element, the second element, and the third element, and the first interval is at least 0.5 times a largest one of the maximum dimensions of the first element, the second element, and the third element.

3. The magnetic sensor according to claim 1, wherein
the first element, the second element, and the third element have the same maximum dimension.

4. The magnetic sensor according to claim 1, wherein
the first interval is less than 2.8 times D.

5. The magnetic sensor according to claim 1, wherein
the first interval is less than 1.9 times D.

6. The magnetic sensor according to claim 4, wherein
the first interval is at least 1.5 times D.

7. The magnetic sensor according to claim 5, wherein
the first interval is at least 1.5 times D.

8. The magnetic sensor according to claim 1, wherein
the second interval is at least 0.5 times D.

9. The magnetic sensor according to claim 1, wherein
the second interval is greater than 0 and at most 3 times D.

10. The magnetic sensor according to claim 9, wherein
the second interval is at least 0.5 times D.

11. The magnetic sensor according to claim 1, wherein
the second interval is greater than the first interval.

12. The magnetic sensor according to claim 11, wherein
the first element, the second element, and the third element are arranged within a rectangular region having two sides extending in the first direction and two sides extending in the second direction, and
a dimension of the rectangular region in the second direction is greater than a dimension of the rectangular region in the first direction.

13. The magnetic sensor according to claim 1, wherein
the planar shape is circular.

14. The magnetic sensor according to claim 1, further comprising
a first electrode and a second electrode spaced from each other in the first direction, wherein
the plurality of magnetoresistive elements further include a fourth element and a fifth element spaced from each other in the first direction,
the first electrode connects the first element and the second element,
the second electrode connects the fourth element and the fifth element, and
the first interval and a distance between the fourth element and the fifth element are greater than a distance between the first electrode and the second electrode.

15. A magnetic sensor comprising:
a first magnetoresistive element; and a second magnetoresistive element arranged at a first interval from the first magnetoresistive element in a first direction, wherein each of the first magnetoresistive element and the second magnetoresistive element includes a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer, the magnetization of the magnetization pinned layer includes a component in the first direction, each of the first magnetoresistive element and the second magnetoresistive element has a planar shape in a plan view from a stacking direction of the magnetization pinned layer, the intermediate layer, and the free layer, the planar shape having a maximum dimension being a greatest distance between any two points on an outer edge of the planar shape, and the first interval is at least 0.5 times D and at most 3 times D, where D is the maximum dimension of at least one of the first magnetoresistive element and the second magnetoresistive element.

16. A magnetic sensor comprising:
a substrate including a first inclined surface and a second inclined surface each extending in a first direction and facing in different directions; and
a plurality of magnetoresistive elements each including a magnetization pinned layer having magnetization whose direction is fixed, a free layer that is capable of having a magnetic vortex structure, the center of the magnetic vortex structure being movable according to a target magnetic field, and an intermediate layer arranged between the magnetization pinned layer and the free layer, wherein
the plurality of magnetoresistive elements include
a first element arranged on the first inclined surface,
a second element arranged on the first inclined surface and spaced from the first element in the first direction,
a third element arranged on the second inclined surface and spaced from the first element in a second direction different from the first direction,
the magnetization pinned layer, the intermediate layer, and the free layer of each of the first element and the second element are stacked in a direction intersecting with the first inclined surface,
the magnetization pinned layer, the intermediate layer, and the free layer of the third element are stacked in a direction intersecting with the second inclined surface,
each of the first element, the second element, and the third element has a planar shape in a plan view from a stacking direction of the magnetization pinned layer, the intermediate layer, and the free layer, the planar shape having a maximum dimension being a greatest distance between any two points on an outer edge of the planar shape, and
an interval between the first element and the third element in a third direction is at least 0.5 times D and at most 3 times D, where D is the maximum dimension of at least one of the first element, the second element, and the third element, the third direction being orthogonal to the first direction, intersecting with the second direction at an angle other than 90 degrees, and being parallel to the first inclined surface.

17. The magnetic sensor according to claim 16, wherein
the substrate further includes a third inclined surface extending in the first direction and facing a direction different from the first inclined surface,
the first inclined surface is located between the second inclined surface and the third inclined surface,
the plurality of magnetoresistive elements further include a fourth element arranged on the third inclined surface and spaced from the first element in the second direction,
the magnetization pinned layer, the intermediate layer, and the free layer of the fourth element are stacked in a direction intersecting with the third inclined surface, and
an interval between the first element and the third element in the third direction is smaller than an interval between the first element and the fourth element in the third direction.

18. The magnetic sensor according to claim 16, wherein
the substrate includes a flat surface and a protrusion protruding from the flat surface,
the protrusion includes the first inclined surface and the second inclined surface, and
each of the first inclined surface and the second inclined surface is inclined with respect to the flat surface.

19. The magnetic sensor according to claim 16, wherein
the substrate includes a flat surface and a recess recessed from the flat surface,
the recess includes the first inclined surface and the second inclined surface, and
each of the first inclined surface and the second inclined surface is inclined with respect to the flat surface.
